(19) United States
(12) Patent Application Publication
(10) Pub. No.: US 2026/0051861 A1
(43) Pub. Date: Feb. 19, 2026

(54) RADIO FREQUENCY CIRCUIT, RADIO FREQUENCY MODULE, AND RADIO FREQUENCY SIGNAL TRANSMISSION METHOD

(71) Applicant: Murata Manufacturing Co., Ltd., Nagaokakyo-shi (JP)

(72) Inventors: Kouta ARAI, Nagaokakyo-shi (JP); Hiroshi Taniguchi, Nagaokakyo-shi (JP); Takeshi Kogure, Nagaokakyo-shi (JP)

(21) Appl. No.: 19/366,938

(22) Filed: Oct. 23, 2025

Related U.S. Application Data
(63) Continuation of application No. PCT/JP2024/006931, filed on Feb. 27, 2024.

(30) Foreign Application Priority Data
Apr. 28, 2023 (JP) 2023-074770

(51) Int. Cl. H03F 3/24; H03F 1/02

(52) U.S. Cl. CPC H03F 3/24; H03F 1/0227; H03F 2200/451

(57) ABSTRACT

A radio frequency circuit is provided that includes a power amplifier connected to an first antenna, a power amplifier connected to a second antenna, a switched-capacitor circuit configured to generate a plurality of discrete voltages based on an input voltage, a first supply modulator configured to selectively output at least one voltage of the plurality of discrete voltages to the power amplifier, and a second supply modulator configured to selectively output at least one voltage of the plurality of discrete voltages to the power amplifier.

### CROSS REFERENCE TO RELATED APPLICATIONS

This application is a continuation of International Application No. PCT/JP2024/006931, filed Feb. 27, 2024, which claims priority to Japanese Patent Application No. 2023-074770, filed Apr. 28, 2023, the contents of each of which are hereby incorporated by reference in their entireties.

### TECHNICAL FIELD

The present disclosure relates to a radio frequency circuit, a radio frequency module, and a radio frequency signal transmission method.

### BACKGROUND

As described in U.S. Pat. No. 8,829,993, for example, power amplification efficiency has recently been improved by applying an envelope tracking (ET) mode to a power amplifier circuit.

However, a power amplification system (e.g., a radio frequency circuit) to be driven in the ET mode requires a power amplifier and a tracker circuit that supplies a power supply voltage in the ET mode to the power amplifier. Further, transmission of radio frequency signals in, for example, a millimeter wave band or a sub-terahertz band requires a vertical polarization transmission path and a horizontal polarization transmission path. Therefore, the size of the amplification system (radio frequency circuit) may increase.

### SUMMARY OF THE INVENTION

In view of the above-noted problem, the exemplary aspects of the present disclosure provide a small-size radio frequency circuit and a small-size radio frequency module including a power amplification system in an ET mode, and a radio frequency signal transmission method that can realize the small-size radio frequency circuit and the small-size radio frequency module.

In an exemplary aspect, a radio frequency circuit is provided that includes a first power amplifier connected to a first vertical polarization antenna; a second power amplifier connected to a first horizontal polarization antenna; a switched-capacitor circuit configured to generate a plurality of discrete voltages based on an input voltage; a first supply modulator configured to selectively output at least one voltage of the plurality of discrete voltages to the first power amplifier; and a second supply modulator configured to selectively output at least one voltage of the plurality of discrete voltages to the second power amplifier.

In another exemplary aspect, a radio frequency module is provided that includes a module laminate; and a first integrated circuit disposed on the module laminate. The first integrated circuit includes at least one switch included in a switched-capacitor circuit, at least one switch included in a first supply modulator, and at least one switch included in a second supply modulator. The switched-capacitor circuit is configured to generate a plurality of discrete voltages based on an input voltage and output the plurality of generated discrete voltages to the first supply modulator and the second supply modulator. A first output terminal of the first supply modulator included in the first integrated circuit is connected to a first power amplifier connected to a first vertical polarization antenna. A second output terminal of the second supply modulator included in the first integrated circuit is connected to a second power amplifier connected to a first horizontal polarization antenna.

In yet another exemplary aspect, a radio frequency signal transmission method is provided that includes generating a plurality of discrete voltages based on an input voltage; selectively supplying at least one voltage of the plurality of discrete voltages to a first power amplifier based on an envelope signal of a first radio frequency signal; selectively supplying at least one voltage of the plurality of discrete voltages to a second power amplifier based on an envelope signal of a second radio frequency signal; amplifying the first radio frequency signal by the first power amplifier and radiating a vertically polarized signal; and amplifying the second radio frequency signal by the second power amplifier and radiating a horizontally polarized signal.

According to the exemplary aspects of the present disclosure, a small-size radio frequency circuit and a small-size radio frequency module including the power amplification system in the ET mode are provided. Moreover, a radio frequency signal transmission method that realizes the small-size radio frequency circuit and the small-size radio frequency module is provided.

### BRIEF DESCRIPTION OF DRAWINGS

FIG. 1A is a graph illustrating an example of transition of a power supply voltage in an average power tracking (APT) mode.

FIG. 1B is a graph illustrating an example of transition of a power supply voltage in an analog ET mode.

FIG. 1C is a graph illustrating an example of transition of a power supply voltage in a digital ET mode.

FIG. 2 is a circuit structure diagram of a radio frequency circuit and a communication device according to a first exemplary embodiment.

FIG. 3 is a circuit block diagram of a tracker circuit according to the first exemplary embodiment.

FIG. 4 is a circuit structure diagram of the tracker circuit according to the first exemplary embodiment.

FIG. 5 is a flowchart illustrating a radio frequency signal transmission method according to the first exemplary embodiment.

FIG. 6A is a plan view of a radio frequency module according to Example 1.

FIG. 6B is a cross-sectional view of the radio frequency module according to Example 1.

FIG. 7A is a plan view of a radio frequency module according to Example 2.

FIG. 7B is a plan view of the radio frequency module according to Example 2.

FIG. 7C is a cross-sectional view of the radio frequency module according to Example 2.

FIG. 8 is a circuit structure diagram of a radio frequency circuit according to a second exemplary embodiment.

FIG. 9 is a cross-sectional view of a radio frequency module according to Example 3.

FIG. 10 is a cross-sectional view of a radio frequency module according to Example 4.

FIG. 11 is a circuit structure diagram of a radio frequency circuit according to Modification 1 of the second exemplary embodiment.

FIG. 12 is a cross-sectional view of a radio frequency module according to Example 5.

FIG. 13 is a cross-sectional view of a radio frequency module according to Example 6.

FIG. 14 is a circuit structure diagram of a radio frequency circuit according to Modification 2 of the second exemplary embodiment.

### DETAILED DESCRIPTION OF EMBODIMENTS

Exemplary embodiments of the present disclosure are described below in detail with reference to the drawings. The following embodiments are comprehensive or specific examples. Values, shapes, materials, components, disposition and connection forms of components, etc. shown in the following embodiments are examples, and are not intended to limit the exemplary aspects.

The drawings are schematic drawings subjected to exaggeration, omission, or ratio control as appropriate to illustrate the exemplary aspects of the present disclosure, and need not be strict illustrations. The shapes, positional relationships, and ratios may be different from actual ones. In the drawings, substantially the same components are represented by the same reference signs, and redundant description may be omitted or simplified.

In the drawings, an x-axis and a y-axis are orthogonal to each other in a plane parallel to the principal surface of a module laminate. Specifically, when the module laminate has a rectangular shape in plan view, the x-axis is parallel to a first side of the module laminate, and the y-axis is parallel to a second side orthogonal to the first side of the module laminate. A z-axis is perpendicular to the principal surface of the module laminate. Its positive direction is an upward direction, and its negative direction is a downward direction.

It is noted that in a circuit structure of the present disclosure, the term “connected” includes not only direct connection at a connection terminal and/or a wiring conductor but also electrical connection via any other circuit element. The phrase “connected between A and B” can indicate connection to both A and B between A and B.

Regarding component disposition in the present disclosure, the phrase “a component is disposed on a board” includes disposition of the component on the principal surface of the board, and disposition of the component inside the board. The phrase “a component is disposed on the principal surface of a board” includes disposition of the component in contact with the principal surface of the board, and disposition of the component above the principal surface without contact with the principal surface (e.g., lamination of the component on another component disposed in contact with the principal surface). The phrase “a component is disposed on the principal surface of a board” may include disposition of the component in a recess formed in the principal surface. Moreover, the phrase “a component is disposed inside a board” includes encapsulation of the component inside a module laminate, disposition of the entire component between the two principal surfaces of the board with part of the component uncovered by the board, and disposition of only part of the component inside the board.

In a circuit connection structure of the present disclosure, the phrase “a component (element) A is disposed in series on a path B” can indicate that both the signal input end and the signal output end of the component (element) A are connected to wires, electrodes, or terminals forming the path B. Moreover, the phrase “a plurality of paths is connected in parallel” can indicate that the first ends of the plurality of paths are connected to the same wire, electrode, or terminal.

Regarding component disposition in the present disclosure, the phrase a “plan view of a module laminate” can indicate that an object or component is viewed while being orthogonally projected onto an xy plane from a positive side of the z-axis. Moreover, the phrase “A overlaps B in plan view” indicates that at least part of the region of A orthogonally projected onto the xy plane overlaps at least part of the region of B orthogonally projected onto the xy plane. The phrase “A is disposed between B and C” indicates that at least one of a plurality of line segments connecting any point inside B and any point inside C passes through A.

Regarding component disposition in the present disclosure, the phrase “A is disposed to adjoin B” can indicate that A and B are disposed in proximity, specifically that no other circuit component is present in the space where A faces B. In other words, the phrase “A is disposed to adjoin B” can indicate that none of a plurality of line segments each extending from any point on the surface of A that faces B along a direction normal to the surface to reach B passes through circuit components other than A and B. The circuit components mean components including an active element and/or a passive element. That is, the circuit components include active components including a transistor or a diode and passive components including an inductor, a transformer, a capacitor, or a resistor, and do not include electromechanical components including a terminal, a connector, or a wire.

In the present disclosure, a “terminal” refers to a point where a conductor inside an element is terminated. When the impedance of a conductor between elements is sufficiently low, the terminal is construed not only as a single point but also as any point on the conductor between the elements or as the entire conductor.

It is also noted that terms such as “parallel” and “perpendicular” showing a relationship between elements, terms such as “rectangular” showing the shape of an element, and numerical ranges do not have strict meanings but have meanings including substantially equal ranges with, for example, errors of several percent.

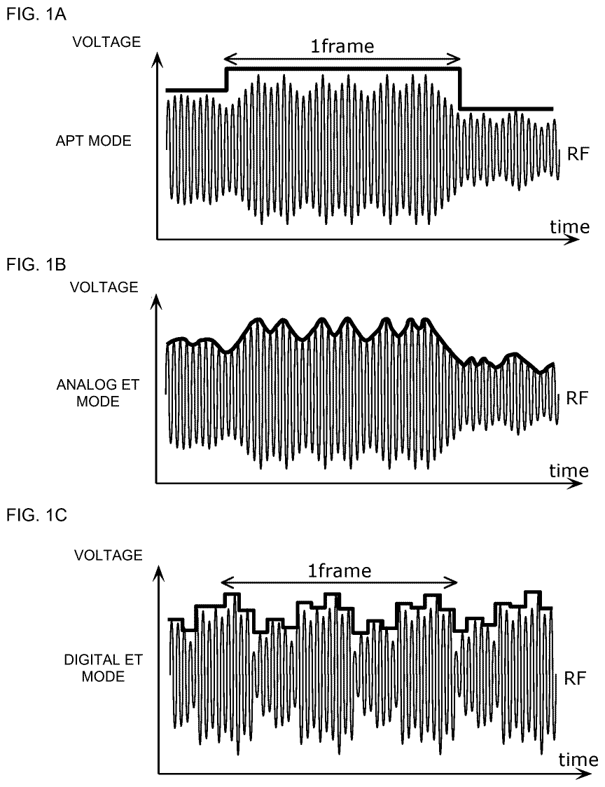

First, tracking modes in which a power amplifier is supplied with a power supply voltage dynamically adjusted with an elapse of time based on a radio frequency signal are described as technologies for amplifying the radio frequency signal with high efficiency. The tracking mode is a mode to dynamically adjust a power supply voltage to be applied to a power amplifier. The tracking modes include several types. An average power tracking (APT) mode and envelope tracking (ET) modes (including an analog ET mode and a digital ET mode) are herein described with reference to FIGS. 1A to IC. In FIGS. 1A to 1C, the horizontal axis represents time, and the vertical axis represents voltage. A thick solid line represents a power supply voltage, and a thin solid line (waveform) represents a modulated signal.

FIG. 1A is a graph illustrating an example of transition of a power supply voltage in the APT mode. In the APT mode, the power supply voltage is varied among a plurality of discrete voltage levels in the unit of one frame based on average power. As a result, the power supply voltage signal forms a rectangular wave.

According to an exemplary aspect, the frame refers to a unit of a radio frequency signal (e.g., modulated signal). For example, in 5GNR (5th Generation New Radio) and LTE (Long Term Evolution), the frame includes ten subframes, each subframe includes a plurality of slots, and each slot includes a plurality of symbols. Moreover, a subframe length is 1 millisecond (ms), and a frame length is 10 ms.

The APT mode is a mode to vary the voltage level in the unit of one frame or larger based on average power and is distinguished from modes to vary the voltage level in a unit smaller than one frame (e.g., subframe, slot, or symbol). For example, a mode to vary the voltage level in the unit of symbol is referred to as a symbol power tracking (SPT) mode and is distinguished from the APT mode.

FIG. 1B is a graph illustrating an example of transition of a power supply voltage in the analog ET mode. In the analog ET mode, the power supply voltage is continuously varied based on an envelope signal to track the envelope of a modulated signal.

The envelope signal is a signal indicating the envelope of a modulated signal. An envelope value is represented by, for example, the square root of (I²+Q²). The expression (I, Q) represents a constellation point. The constellation point is a point on a constellation diagram for a signal modulated by digital modulation. For example, (I, Q) is determined by a BBIC (Baseband Integrated Circuit) based on transmission information.

FIG. 1C is a graph illustrating an example of transition of a power supply voltage in the digital ET mode. In the digital ET mode, the power supply voltage is varied among a plurality of discrete voltage levels within one frame based on an envelope signal to track the envelope of a modulated signal. As a result, the power supply voltage signal forms a rectangular wave.

### First Exemplary Embodiment

A communication device 9 according to this embodiment corresponds to user equipment (UE) that communicates with other equipment and base stations using radio signals in a millimeter wave band or a sub-terahertz band, and is typically a mobile phone, a smartphone, a tablet computer, a wearable device, etc. The communication device 9 may be an IoT (Internet of Things) sensor device, a medical/healthcare device, a car, an unmanned aerial vehicle (UAV) (so-called drone), or an automated guided vehicle (AGV). The communication device 9 can be configured to function as a base station. The communication device 9 may be UE or a base station in a cellular network.

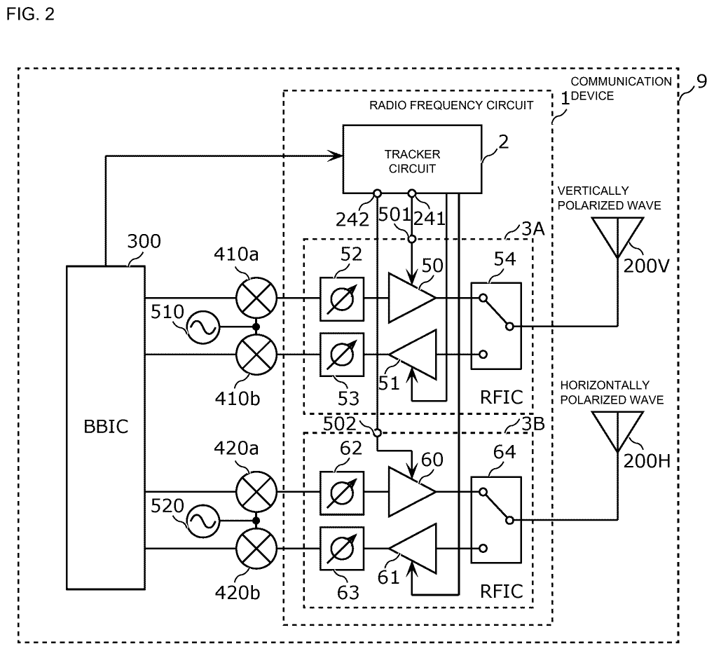

The circuit structure of the communication device 9 and a radio frequency circuit 1 according to this embodiment is described with reference to FIG. 2. FIG. 2 is a circuit structure diagram of the radio frequency circuit 1 and the communication device 9 according to the first embodiment.

FIG. 2 illustrates an exemplary circuit structure. The communication device 9 and the radio frequency circuit 1 may be mounted using any one of a wide variety of circuit mounting and circuit technologies. Thus, the following description of the communication device 9 and the radio frequency circuit 1 is not to be construed as restrictive.

### [1.1 Circuit Structure of Communication Device 9 and Radio Frequency Circuit 1]

First, the communication device 9 according to this embodiment is described with reference to FIG. 2. The communication device 9 includes the radio frequency circuit 1, antennas 200V and 200H, a BBIC (BaseBand signal Integrated Circuit) 300, mixers 410a, 410b, 420a, and 420b, and local oscillators 510 and 520.

In the exemplary aspect, the radio frequency circuit 1 includes a tracker circuit 2 and RFICs (Radio Frequency Integrated Circuits) 3A and 3B.

The RFIC 3A is an example of a signal processing circuit, includes phase shift circuits 52 and 53, a power amplifier 50, a low-noise amplifier 51, a switch 54, and an input terminal 501, and is configured to output a signal in a radio frequency band to the antenna 200V.

The RFIC 3B is an example of the signal processing circuit, includes phase shift circuits 62 and 63, a power amplifier 60, a low-noise amplifier 61, a switch 64, and an input terminal 502, and is configured to output a signal in the radio frequency band to the antenna 200H.

The phase shift circuit 52 is an example of a first phase shift circuit, is connected to an input end of the power amplifier 50 and adjusts the phase of a transmission signal in the radio frequency band that is output from the mixer 410a. The phase shift circuit 53 adjusts the phase of a reception signal in the radio frequency band that is output from the low-noise amplifier 51. The phase shift circuit 62 is an example of a second phase shift circuit, is connected to an input end of the power amplifier 60 and adjusts the phase of a transmission signal in the radio frequency band that is output from the mixer 420a. The phase shift circuit 63 adjusts the phase of a reception signal in the radio frequency band that is output from the low-noise amplifier 61.

The power amplifier 50 is an example of a first power amplifier, is connected to the antenna 200V via the switch 54, and amplifies the transmission signal in the radio frequency band that is output from the phase shift circuit 52. The low-noise amplifier 51 amplifies the reception signal in the radio frequency band that is output from the antenna 200V. The power amplifier 50 includes a first amplification transistor. The first amplification transistor is disposed in series on a path connecting the phase shift circuit 52 and the switch 54.

The power amplifier 60 is an example of a second power amplifier, is connected to the antenna 200H via the switch 64, and amplifies the transmission signal in the radio frequency band that is output from the phase shift circuit 62. The low-noise amplifier 61 amplifies the reception signal in the radio frequency band that is output from the antenna 200H. The power amplifier 60 includes a second amplification transistor. The second amplification transistor is disposed in series on a path connecting the phase shift circuit 62 and the switch 64.

The switch 54 is configured to switch the connection between the antenna 200V and an output end of the power amplifier 50 and the connection between the antenna 200V and an input end of the low-noise amplifier 51. The switch 64 switches the connection between the antenna 200H and an output end of the power amplifier 60 and the connection between the antenna 200H and an input end of the low-noise amplifier 61.

The input terminal 501 is a terminal that is connected to the power amplifier 50 and receives a power supply voltage V_{ET1} supplied from the tracker circuit 2. The input terminal 502 is a terminal that is connected to the power amplifier 60 and receives a power supply voltage V_{ET2} supplied from the tracker circuit 2.

The power amplifiers 50 and 60 and the low-noise amplifiers 51 and 61 can each amplify a radio frequency signal in a millimeter wave band or a sub-terahertz band. The power amplifiers 50 and 60 and the low-noise amplifiers 51 and 61 can each amplify a radio frequency signal in a frequency band predefined by a standardizing body etc. (e.g., 3GPP® (3rd Generation Partnership Project) or IEEE (Institute of Electrical and Electronics Engineers)) for communication systems constructed using a radio access technology (RAT).

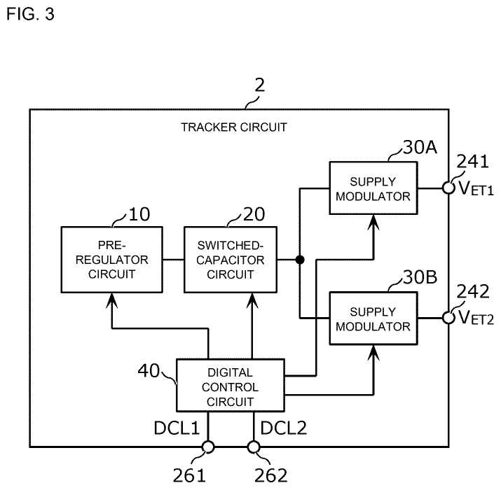

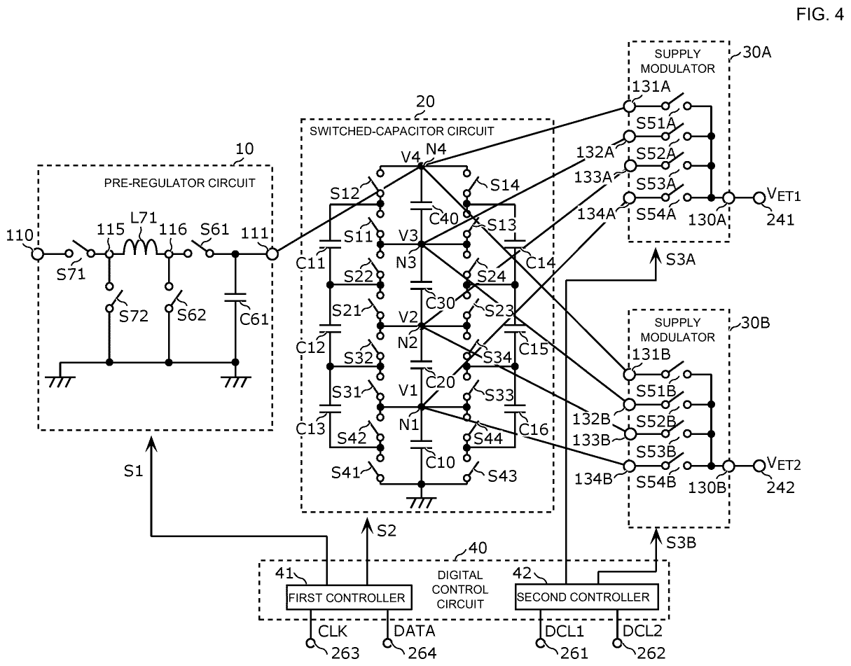

The tracker circuit 2 is configured to generate supply voltages to the power amplifiers 50 and 60 and the low-noise amplifiers 51 and 61 that amplify signals in the radio frequency band and includes at least one integrated circuit. Specifically, the tracker circuit 2 supplies variable voltages in the digital ET mode or the SPT mode to the power amplifiers 50 and 60 based on envelope signals supplied from the BBIC 300. The tracker circuit 2 supplies constant voltages to the low-noise amplifiers 51 and 61. A circuit structure example of the tracker circuit 2 is described later with reference to FIGS. 3 and 4.

At least one of the power amplifier 50, the low-noise amplifier 51, and the switch 54 may be omitted from the RFIC 3A in an exemplary aspect. Moreover, at least one of the power amplifier 60, the low-noise amplifier 61, and the switch 64 may be omitted from the RFIC 3B.

The RFICs 3A and 3B may be a single RFIC in an exemplary aspect.

The antenna 200V is an example of a first vertical polarization antenna, and vertically polarizes and is configured to radiate the transmission signal in the radio frequency band that is output from the radio frequency circuit 1. The antenna 200V outputs, to the radio frequency circuit 1, a received vertically polarized signal in the radio frequency band. The antenna 200H is an example of a first horizontal polarization antenna and is configured to horizontally polarize and radiate the transmission signal in the radio frequency band that is output from the radio frequency circuit 1. The antenna 200H outputs, to the radio frequency circuit 1, a received horizontally polarized signal in the radio frequency band. The antennas 200V and 200H may be omitted from the communication device 9 in an exemplary aspect.

In an exemplary aspect, the vertical polarization angle may include an error range of about 10% of 180° instead of being strictly 90° (or 270°) relative to the reference (e.g., antenna radiation plane). That is, the vertical polarization angle may be in a range of (90°±18°) or (270°±18°) relative to the reference (e.g., antenna radiation plane). The horizontal polarization angle may include an error range of about 10% of 180° instead of being strictly 0° (or 180°) relative to the reference (e.g., antenna radiation plane). That is, the horizontal polarization angle may be in a range of (0°±18°) or (180°±18°) relative to the reference (e.g., antenna radiation plane).

The BBIC 300 is an integrated circuit that is configured to generate a baseband transmission signal and process a baseband reception signal. The BBIC 300 supplies an envelope signal to the tracker circuit 2 of the radio frequency circuit 1.

The mixer 410a up-converts the transmission signal generated by the BBIC 300 based on a local oscillation wave from the local oscillator 510, and outputs the up-converted transmission signal to the transmission path of the RFIC 3A. The mixer 410b down-converts the reception signal output from the receive path of the RFIC 3A based on a local oscillation wave from the local oscillator 510, and outputs the down-converted reception signal to the BBIC 300. The mixer 420a up-converts the transmission signal generated by the BBIC 300 based on a local oscillation wave from the local oscillator 520, and outputs the up-converted transmission signal to the transmission path of the RFIC 3B. The mixer 420b down-converts the reception signal output from the receive path of the RFIC 3B based on a local oscillation wave from the local oscillator 520, and outputs the down-converted reception signal to the BBIC 300.

At least one of the mixers 410a and 410b and the local oscillator 510 may be included in the RFIC 3A. At least one of the mixers 420a and 420b and the local oscillator 520 may be included in the RFIC 3B.

### [1.2 Circuit Structure of Tracker Circuit 2]

FIG. 3 is a circuit block diagram of the tracker circuit 2 according to the first embodiment. The tracker circuit 2 includes a pre-regulator circuit 10, a switched-capacitor circuit 20, supply modulators 30A and 30B, a digital control circuit 40, output terminals 241 and 242, and control signal terminals 261 and 262.

The pre-regulator circuit 10 can convert an input voltage supplied from a direct current power source (not illustrated) into an adjusted voltage using a power inductor. The pre-regulator circuit 10 includes the power inductor and a switch. The power inductor is an inductor to be used to step up and/or down a direct current (DC) voltage. The power inductor is disposed in series on a direct current path. The power inductor may be connected between the direct current path and a ground (i.e., disposed parallel to the direct current path). The pre-regulator circuit 10 may be referred to as a magnetic regulator or a DC-DC converter. The pre-regulator circuit 10 may omit the power inductor in an exemplary aspect.

The switched-capacitor circuit 20 includes a plurality of capacitors and a plurality of switches, and can be configured to generate a plurality of discrete voltages having a plurality of discrete voltage levels from the adjusted voltage supplied from the pre-regulator circuit 10. The switched-capacitor circuit 20 may be referred to as a switched-capacitor voltage ladder.

The supply modulator 30A is an example of a first supply modulator and is configured to select at least one of the plurality of discrete voltages generated by the switched-capacitor circuit 20 and output it to the power amplifier 50. The supply modulator 30B is an example of a second supply modulator and is configured to select at least one of the plurality of discrete voltages generated by the switched-capacitor circuit 20 and output it to the power amplifier 60.

The digital control circuit 40 can be configured to control the pre-regulator circuit 10, the switched-capacitor circuit 20, and the supply modulators 30A and 30B based on digital control signals from the BBIC 300.

It is noted that the tracker circuit 2 need not include part of the pre-regulator circuit 10 and the digital control circuit 40. For example, the tracker circuit 2 may omit the pre-regulator circuit 10 in an exemplary aspect. Any combination of the pre-regulator circuit 10, the switched-capacitor circuit 20, and the supply modulators 30A and 30B may be integrated into a single circuit. The tracker circuit 2 may include a voltage supply circuit (e.g., DC-DC converter) having another circuit structure instead of the pre-regulator circuit 10 and the switched-capacitor circuit 20. The tracker circuit 2 may include a filter circuit that is connected between the supply modulator 30A and the power amplifier 50 and attenuates noise from the plurality of discrete voltages. The tracker circuit 2 may include a filter circuit that is connected between the supply modulator 30B and the power amplifier 60 and attenuates noise from the plurality of discrete voltages.

With the above structure, the tracker circuit 2 is configured to supply the power supply voltage V_{ET1} that is one of the plurality of discrete voltages from the supply modulator 30A to the power amplifier 50, and to supply the power supply voltage V_{ET2} that is one of the plurality of discrete voltages from the supply modulator 30B to the power amplifier 60.

With the above structure of the radio frequency circuit 1, the plurality of discrete voltages to be supplied to the power amplifiers 50 and 60 is generated by the same switched-capacitor circuit 20. Thus, the tracker circuit 2 can be downsized, thereby providing a small-size radio frequency circuit 1 including the power amplification system in the ET mode.

Next, the circuit structure of each circuit included in the tracker circuit 2 is described with reference to FIG. 4. FIG. 4 is a circuit structure diagram of the tracker circuit 2 according to the first embodiment.

### [1.2.1 Circuit Structure of Switched-Capacitor Circuit 20]

First, the circuit structure of the switched-capacitor circuit 20 is described. The switched-capacitor circuit 20 includes capacitors C11 to C16, capacitors C10, C20, C30, and C40, and switches S11 to S14, S21 to S24, S31 to S34, and S41 to S44. Energy and charge are input from the pre-regulator circuit 10 to the switched-capacitor circuit 20 at a node N4 and drawn from the switched-capacitor circuit 20 to the supply modulators 30A and 30B at nodes N1 to N4.

The capacitors C11 to C16 can be configured as flying capacitors (may also be referred to as transfer capacitors). That is, the capacitors C11 to C16 are configured to step up or down the adjusted voltage supplied from the pre-regulator circuit 10. More specifically, the capacitors C11 to C16 move the charges between the capacitors C11 to C16 and the nodes N1 to N4 to maintain voltages V1 to V4 (voltages relative to a ground potential) that satisfy V1:V2:V3:V4=1:2:3:4 at the four nodes N1 to N4. The voltages V1 to V4 correspond to the plurality of discrete voltages having the plurality of discrete voltage levels.

The capacitor C11 includes two electrodes. One of the two electrodes of the capacitor C11 is connected to one end of the switch S11 and one end of the switch S12. The other of the two electrodes of the capacitor C11 is connected to one end of the switch S21 and one end of the switch S22. The capacitor C12 includes two electrodes. One of the two electrodes of the capacitor C12 is connected to one end of the switch S21 and one end of the switch S22. The other of the two electrodes of the capacitor C12 is connected to one end of the switch S31 and one end of the switch S32. The capacitor C13 includes two electrodes. One of the two electrodes of the capacitor C13 is connected to one end of the switch S31 and one end of the switch S32. The other of the two electrodes of the capacitor C13 is connected to one end of the switch S41 and one end of the switch S42. The capacitor C14 includes two electrodes. One of the two electrodes of the capacitor C14 is connected to one end of the switch S13 and one end of the switch S14. The other of the two electrodes of the capacitor C14 is connected to one end of the switch S23 and one end of the switch S24. The capacitor C15 includes two electrodes. One of the two electrodes of the capacitor C15 is connected to one end of the switch S23 and one end of the switch S24. The other of the two electrodes of the capacitor C15 is connected to one end of the switch S33 and one end of the switch S34. The capacitor C16 includes two electrodes. One of the two electrodes of the capacitor C16 is connected to one end of the switch S33 and one end of the switch S34. The other of the two electrodes of the capacitor C16 is connected to one end of the switch S43 and one end of the switch S44.

The set of the capacitors C11 and C14, the set of the capacitors C12 and C15, and the set of the capacitors C13 and C16 can each be charged and discharged complementarily by repeating a first phase and a second phase.

Specifically, in the first phase, the switches S12, S13, S22, S23, S32, S33, S42, and S43 are turned ON. Thus, for example, one of the two electrodes of the capacitor C12 is connected to the node N3, the other of the two electrodes of the capacitor C12 and one of the two electrodes of the capacitor C15 are connected to the node N2, and the other of the two electrodes of the capacitor C15 is connected to the node N1. In the second phase, the switches S11, S14, S21, S24, S31, S34, S41, and S44 are turned ON. Thus, for example, one of the two electrodes of the capacitor C15 is connected to the node N3, the other of the two electrodes of the capacitor C15 and one of the two electrodes of the capacitor C12 are connected to the node N2, and the other of the two electrodes of the capacitor C12 is connected to the node N1.

Through the repetition of the first phase and the second phase, for example, when one of the capacitors C12 and C15 is being charged from the node N2, the other of the capacitors C12 and C15 can be discharged to the capacitor C30. That is, the capacitors C12 and C15 can be charged and discharged complementarily.

Similarly to the set of the capacitors C12 and C15, the set of the capacitors C11 and C14 and the set of the capacitors C13 and C16 can each be charged and discharged complementarily by repeating the first phase and the second phase.

The capacitors C10, C20, C30, and C40 can be configured as smoothing capacitors. That is, the capacitors C10, C20, C30, and C40 are configured to keep and smooth the voltages V1 to V4 at the nodes N1 to N4.

The capacitor C10 is connected between the node N1 and the ground. Specifically, one of the two electrodes of the capacitor C10 is connected to the node N1. The other of the two electrodes of the capacitor C10 is connected to the ground. The capacitor C20 is connected between the nodes N2 and N1. Specifically, one of the two electrodes of the capacitor C20 is connected to the node N2. The other of the two electrodes of the capacitor C20 is connected to the node N1. The capacitor C30 is connected between the nodes N3 and N2. Specifically, one of the two electrodes of the capacitor C30 is connected to the node N3. The other of the two electrodes of the capacitor C30 is connected to the node N2. The capacitor C40 is connected between the nodes N4 and N3. Specifically, one of the two electrodes of the capacitor C40 is connected to the node N4. The other of the two electrodes of the capacitor C40 is connected to the node N3.

The switch S11 is connected between one of the two electrodes of the capacitor C11 and the node N3. Specifically, one end of the switch S11 is connected to one of the two electrodes of the capacitor C11. The other end of the switch S11 is connected to the node N3. The switch S12 is connected between one of the two electrodes of the capacitor C11 and the node N4. Specifically, one end of the switch S12 is connected to one of the two electrodes of the capacitor C11. The other end of the switch S12 is connected to the node N4.

The switch S21 is connected between one of the two electrodes of the capacitor C12 and the node N2. Specifically, one end of the switch S21 is connected to one of the two electrodes of the capacitor C12 and the other of the two electrodes of the capacitor C11. The other end of the switch S21 is connected to the node N2. The switch S22 is connected between one of the two electrodes of the capacitor C12 and the node N3. Specifically, one end of the switch S22 is connected to one of the two electrodes of the capacitor C12 and the other of the two electrodes of the capacitor C11. The other end of the switch S22 is connected to the node N3.

The switch S31 is connected between the other of the two electrodes of the capacitor C12 and the node N1. Specifically, one end of the switch S31 is connected to the other of the two electrodes of the capacitor C12 and one of the two electrodes of the capacitor C13. The other end of the switch S31 is connected to the node N1. The switch S32 is connected between the other of the two electrodes of the capacitor C12 and the node N2. Specifically, one end of the switch S32 is connected to the other of the two electrodes of the capacitor C12 and one of the two electrodes of the capacitor C13. The other end of the switch S32 is connected to the node N2. That is, the other end of the switch S32 is connected to the other end of the switch S21.

The switch S41 is connected between the other of the two electrodes of the capacitor C13 and the ground. Specifically, one end of the switch S41 is connected to the other of the two electrodes of the capacitor C13. The other end of the switch S41 is connected to the ground. The switch S42 is connected between the other of the two electrodes of the capacitor C13 and the node N1. Specifically, one end of the switch S42 is connected to the other of the two electrodes of the capacitor C13. The other end of the switch S42 is connected to the node N1. That is, the other end of the switch S42 is connected to the other end of the switch S31.

The switch S13 is connected between one of the two electrodes of the capacitor C14 and the node N3. Specifically, one end of the switch S13 is connected to one of the two electrodes of the capacitor C14. The other end of the switch S13 is connected to the node N3. That is, the other end of the switch S13 is connected to the other end of the switch S11 and the other end of the switch S22. The switch S14 is connected between one of the two electrodes of the capacitor C14 and the node N4. Specifically, one end of the switch S14 is connected to one of the two electrodes of the capacitor C14. The other end of the switch S14 is connected to the node N4. That is, the other end of the switch S14 is connected to the other end of the switch S12.

The switch S23 is connected between one of the two electrodes of the capacitor C15 and the node N2. Specifically, one end of the switch S23 is connected to one of the two electrodes of the capacitor C15 and the other of the two electrodes of the capacitor C14. The other end of the switch S23 is connected to the node N2. That is, the other end of the switch S23 is connected to the other end of the switch S21 and the other end of the switch S32. The switch S24 is connected between one of the two electrodes of the capacitor C15 and the node N3. Specifically, one end of the switch S24 is connected to one of the two electrodes of the capacitor C15 and the other of the two electrodes of the capacitor C14. The other end of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. Specifically, one end of the switch S33 is connected to the other of the two electrodes of the capacitor C15 and one of the two electrodes of the capacitor C16. The other end of the switch S33 is connected to the node N1. That is, the other end of the switch S33 is connected to the other end of the switch S31 and the other end of the switch S42. The switch S34 is connected between the other of the two electrodes of the capacitor C15 and the node N2. Specifically, one end of the switch S34 is connected to the other of the two electrodes of the capacitor C15 and one of the two electrodes of the capacitor C16. The other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. Specifically, one end of the switch S43 is connected to the other of the two electrodes of the capacitor C16. The other end of the switch S43 is connected to the ground. The switch S44 is connected between the other of the two electrodes of the capacitor C16 and the node N1. Specifically, one end of the switch S44 is connected to the other of the two electrodes of the capacitor C16. The other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched ON and OFF complementarily based on a control signal S2. Specifically, in the first phase, the first set of switches is turned ON, and the second set of switches is turned OFF. Conversely, in the second phase, the first set of switches is turned OFF, and the second set of switches is turned ON.

For example, charging is performed from the capacitors C11 to C13 to the capacitors C10 to C40 in one of the first phase and the second phase, and charging is performed from the capacitors C14 to C16 to the capacitors C10 to C40 in the other of the first phase and the second phase. That is, the capacitors C10 to C40 are constantly charged from the capacitors C11 to C13 or the capacitors C14 to C16. Therefore, even when currents flow at a high rate from the nodes N1 to N4 to the supply modulators 30A and 30B, the nodes N1 to N4 are replenished with charges at a high rate. Thus, potential fluctuations at the nodes N1 to N4 can be suppressed.

Through the above operations, substantially equal voltages can be maintained at both ends of each of the capacitors C10, C20, C30, and C40 of the switched-capacitor circuit 20. Specifically, at the four nodes labeled with V1 to V4, the voltages V1 to V4 (voltages relative to the ground potential) that satisfy V1:V2:V3:V4=1:2:3:4 are maintained. The voltage levels of the voltages V1 to V4 correspond to the plurality of discrete voltage levels suppliable to the supply modulators 30A and 30B by the switched-capacitor circuit 20.

It is noted that the voltage ratio (V1:V2:V3:V4) is not limited to (1:2:3:4). For example, the voltage ratio (V1:V2:V3:V4) may be (1:2:4:8) in an alternative exemplary aspect.

It is noted that the structure of the switched-capacitor circuit 20 illustrated in FIG. 4 is an example and is not to be construed as limitative. In FIG. 4, the switched-capacitor circuit 20 is configured to supply the four discrete voltages, but the number of discrete voltages is not limited to this number. Instead, the switched-capacitor circuit 20 may be configured to supply any number of discrete voltages as long as the number is two or more. For example, when two discrete voltages are supplied, the switched-capacitor circuit 20 includes at least the capacitors C12 and C15 and the switches S21 to S24 and S31 to S34.

### [1.2.2 Circuit Structures of Supply Modulators 30A and 30B]

Next, the circuit structures of the supply modulators 30A and 30B are described. The supply modulator 30A includes input terminals 131A to 134A, switches S51A to S54A, and output terminals 130A and 241. The supply modulator 30B includes input terminals 131B to 134B, switches S51B to S54B, and output terminals 130B and 242.

The output terminal 130A is connected to the power amplifier 50 via the output terminal 241. The output terminal 130A is a terminal for supplying the power supply voltage selected from among the voltages V1 to V4 to the power amplifier 50. The output terminal 130A and the output terminal 241 may be a single output terminal.

The input terminals 131A to 134A are connected to the nodes N4 to N1 of the switched-capacitor circuit 20, respectively. The input terminals 131A to 134A are terminals for receiving the voltages V4 to V1 from the switched-capacitor circuit 20, respectively.

The switch S51A is connected between the input terminal 131A and the output terminal 130A. Specifically, the switch S51A includes a terminal connected to the input terminal 131A, and a terminal connected to the output terminal 130A. In this connection structure, the switch S51A can switch connection and disconnection between the input terminal 131A and the output terminal 130A by being switched ON and OFF based on a control signal S3A. The switch S52A is connected between the input terminal 132A and the output terminal 130A. Specifically, the switch S52A includes a terminal connected to the input terminal 132A, and a terminal connected to the output terminal 130A. In this connection structure, the switch S52A can switch connection and disconnection between the input terminal 132A and the output terminal 130A by being switched ON and OFF based on the control signal S3A. The switch S53A is connected between the input terminal 133A and the output terminal 130A. Specifically, the switch S53A includes a terminal connected to the input terminal 133A, and a terminal connected to the output terminal 130A. In this connection structure, the switch S53A can switch connection and disconnection between the input terminal 133A and the output terminal 130A by being switched ON and OFF based on the control signal S3A. The switch S54A is connected between the input terminal 134A and the output terminal 130A. Specifically, the switch S54A includes a terminal connected to the input terminal 134A, and a terminal connected to the output terminal 130A. In this connection structure, the switch S54A can switch connection and disconnection between the input terminal 134A and the output terminal 130A by being switched ON and OFF based on the control signal S3A.

The switches S51A to S54A are controlled to be turned ON exclusively. That is, only one of the switches S51A to S54A is turned ON, and the remainder of the switches S51A to S54A is turned OFF. Thus, the supply modulator 30A can output one voltage selected from among the voltages V1 to V4.

It is noted that the structure of the supply modulator 30A illustrated in FIG. 4 is an example and is not to be construed as limitative. In particular, the switches S51A to S54A may have any structure as long as at least one of the four input terminals 131A to 134A can selectively be connected to the output terminal 130A. For example, the supply modulator 30A may further include a switch connected between a section including the switches S51A to S53A and a section including the switch S54A and the output terminal 130A. For example, the supply modulator 30A may further include a switch connected between a section including the switches S51A and S52A and a section including the switches S53A and S54A and the output terminal 130A.

In an exemplary aspect, when voltages having two discrete voltage levels are supplied from the switched-capacitor circuit 20, the supply modulator 30A includes at least two of the switches S51A to S54A.

It is noted that the structure of the supply modulator 30B is not described because the input terminals 131A to 134A of the supply modulator 30A are replaced with the input terminals 131B to 134B and the switches S51A to S54A of the supply modulator 30A are replaced with the switches S51B to S54B. The output terminal 130B is connected to the power amplifier 60 via the output terminal 242. The output terminal 130B is a terminal for supplying the power supply voltage selected from among the voltages V1 to V4 to the power amplifier 60. The output terminal 130B and the output terminal 242 may be a single output terminal.

### [1.2.3 Circuit Structure of Pre-Regulator Circuit 10]

Next, the circuit structure of the pre-regulator circuit 10 is described. The pre-regulator circuit 10 includes an input terminal 110, an output terminal 111, inductor connection terminals 115 and 116, switches S61, S62, S71, and S72, a power inductor L71, and a capacitor C61.

The input terminal 110 is an input terminal for the direct current voltage. The output terminal 111 is an output terminal for the voltage V4. That is, the output terminal 111 is a terminal for supplying the voltage V4 to the switched-capacitor circuit 20. The output terminal 111 is connected to the node N4 of the switched-capacitor circuit 20. The output terminal 111 may be connected to any one of the nodes N3 to N1 of the switched-capacitor circuit 20. The inductor connection terminal 115 is connected to one end of the power inductor L71. The inductor connection terminal 116 is connected to the other end of the power inductor L71.

The switch S71 is connected between the input terminal 110 and one end of the power inductor L71 and can switch connection and disconnection between the input terminal 110 and one end of the power inductor L71 by being switched ON and OFF based on a control signal S1. The switch S72 is connected between one end of the power inductor L71 and the ground and can switch connection and disconnection between one end of the power inductor L71 and the ground by being switched ON and OFF based on the control signal S1.

The switch S61 is connected between the other end of the power inductor L71 and the output terminal 111 and can switch connection and disconnection between the other end of the power inductor L71 and the output terminal 111 by being switched ON and OFF based on the control signal S1. The switch S62 is connected between the other end of the power inductor L71 and the ground and can switch connection and disconnection between the other end of the power inductor L71 and the ground by being switched ON and OFF based on the control signal S1.

One of the two electrodes of the capacitor C61 is connected to the switch S61 and the output terminal 111. The other of the two electrodes of the capacitor C61 is connected to the ground. The capacitor C61 is configured as a smoothing capacitor.

The pre-regulator circuit 10 having the above structure can supply charge to the switched-capacitor circuit 20 via the output terminal 111.

In an exemplary aspect, when the input voltage is converted into one adjusted voltage, the pre-regulator circuit 10 includes at least the switches S71 and S72 and the power inductor L71.

### [1.2.4 Circuit Structure of Digital Control Circuit 40]

Next, the circuit structure of the digital control circuit 40 is described. The digital control circuit 40 includes a first controller 41 and a second controller 42.

The first controller 41 can be configured to generate the control signals S1 and S2 by processing a serial data signal (DATA) supplied from the BBIC 300 via a control signal terminal 264 based on a clock signal (CLK) supplied from the BBIC 300 via a control signal terminal 263. In an exemplary aspect, the serial data signal refers to a data signal transmitted by one bit at a time on a single signal wire or line.

The control signal S1 is a signal for controlling the opening and closing of the switches S61, S62, S71, and S72 included in the pre-regulator circuit 10. The control signal S2 is a signal for controlling the opening and closing of the switches S11 to S14, S21 to S24, S31 to S34, and S41 to S44 included in the switched-capacitor circuit 20.

A signal wire different from that for the serial data signal is used for the clock signal for the first controller 41 to process the serial data signal, but is not to be construed as limitative. For example, the clock signal may be transmitted on the same signal wire as that for the serial data signal.

In this embodiment, the single serial data signal is used to control the pre-regulator circuit 10 and the switched-capacitor circuit 20, but a plurality of serial data signals may be used.

The second controller 42 can be configured to generate the control signals S3A and S3B by processing digital control logic/line (DCL) signals (DCL1, DCL2) supplied from the BBIC 300 via the control signal terminals 261 and 262. The DCL signals are an example of parallel data signals. The parallel data signals refer to data signals transmitted simultaneously in parallel on a plurality of signal wires or lines.

The DCL signal (DCL1) is an example of a first parallel data signal and is generated based on a first envelope signal of a first radio frequency signal by the BBIC 300 when the digital ET mode is applied to the power amplifier 50. The DCL signal (DCL2) is an example of a second parallel data signal and is generated based on a second envelope signal of a second radio frequency signal by the BBIC 300 when the digital ET mode is applied to the power amplifier 60.

The control signal S3A is a signal for controlling the opening and closing of the switches S51A to S54A included in the supply modulator 30A when the digital ET mode is applied to the power amplifier 50. The control signal S3B is a signal for controlling the opening and closing of the switches S51B to S54B included in the supply modulator 30B when the digital ET mode is applied to the power amplifier 60.

Thus, the supply modulator 30A selects at least one of the plurality of discrete voltages in accordance with the DCL signal (DCL1). The supply modulator 30B selects at least one of the plurality of discrete voltages in accordance with the DCL signal (DCL2).

The DCL signals (DCL1, DCL2) are each, for example, a combination of two 1-bit signals. The voltages V1 to V4 are each represented by two 1-bit signals. For example, V1, V2, V3, and V4 are represented by “00,” “01,” “10,” and “11,” respectively. The voltage level may be represented using the Gray code in an alternative exemplary aspect.

The supply modulators 30A and 30B can supply the power supply voltages individually to the power amplifiers 50 and 60 by being controlled based on the different DCL signals (DCL1 and DCL2). Thus, the power supply voltages to be supplied to the power amplifiers 50 and 60 can be optimized. Therefore, the distortion characteristics of the power amplifiers 50 and 60 can be optimized. In an exemplary aspect, when the power amplifiers 50 and 60 are operated by MIMO (Multiple-Input and Multiple-Output), the parameters of DPD (Digital Pre-Distortion) circuits disposed upstream of the power amplifiers 50 and 60 can be set individually. Therefore, the communication throughput can be improved.

The supply modulators 30A and 30B may be controlled based on the same DCL signal (e.g., DCL1). In this case, the same reference signal is transmitted from the antennas 200V and 200H, and the optimum communication state can therefore be obtained. Thus, the communication coverage can be improved.

### [1.3 Radio Frequency Signal Transmission Method]

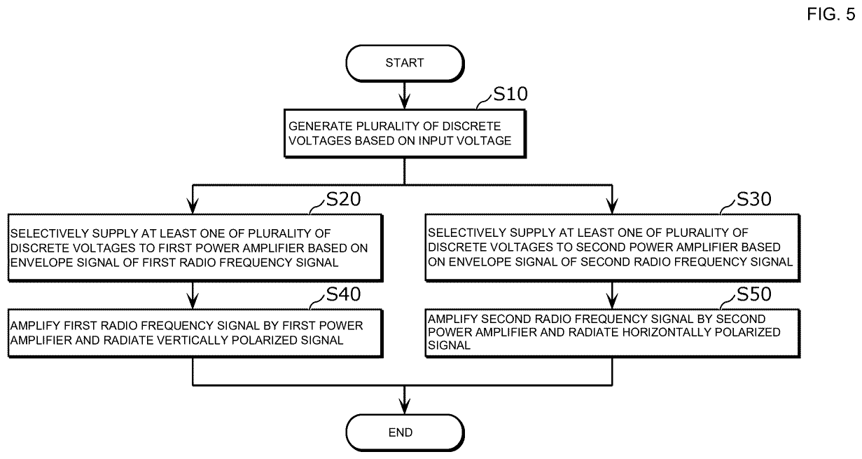

Next, a radio frequency signal transmission method to be performed by the communication device 9 having the above structure is described with reference to FIG. 5. FIG. 5 is a flowchart illustrating the radio frequency signal transmission method according to this embodiment.

First, the switched-capacitor circuit 20 generates a plurality of discrete voltages based on an input voltage (adjusted voltage obtained by conversion of the input voltage) from the pre-regulator circuit 10 (S10).

Next, the supply modulator 30A selectively supplies at least one of the plurality of discrete voltages generated by the switched-capacitor circuit 20 to the power amplifier 50 based on the first envelope signal of the first radio frequency signal (S20).

The supply modulator 30B selectively supplies at least one of the plurality of discrete voltages generated by the switched-capacitor circuit 20 to the power amplifier 60 based on the second envelope signal of the second radio frequency signal (S30).

Next, the power amplifier 50 amplifies the first radio frequency signal. The amplified first radio frequency signal is input to the antenna 200V, and the antenna 200V radiates a vertically polarized signal (S40).

The power amplifier 60 amplifies the second radio frequency signal. The amplified second radio frequency signal is input to the antenna 200H, and the antenna 200H radiates a horizontally polarized signal (S50).

With this method, the first radio frequency signal to be output to the vertical polarization antenna and the second radio frequency signal to be output to the horizontal polarization antenna can be amplified in the ET mode. At this time, the plurality of discrete voltages (power supply voltages V_{ET1} and V_{ET2}) to be supplied to the power amplifier 50 that amplifies the first radio frequency signal and the power amplifier 60 that amplifies the second radio frequency signal is generated by the same switched-capacitor circuit 20. That is, the tracker circuit 2 can be downsized. Thus, a small-size radio frequency circuit 1 including the power amplification system in the ET mode can be provided.

The timing to selectively supply at least one of the plurality of discrete voltages to the power amplifier 50 based on the envelope signal of the first radio frequency signal (S20) is desirably the same as the timing to selectively supply at least one of the plurality of discrete voltages to the power amplifier 60 based on the envelope signal of the second radio frequency signal (S30).

With this setting, the power supply voltage V_{ET1} to be supplied to the power amplifier 50 and the power supply voltage V_{ET2} to be supplied to the power amplifier 60 are output from different supply modulators. Therefore, the vertically polarized signal and the horizontally polarized signal can be radiated with high efficiency and high accuracy.

### [1.4 Mounting Example of Radio Frequency Module 1A According to Example 1]

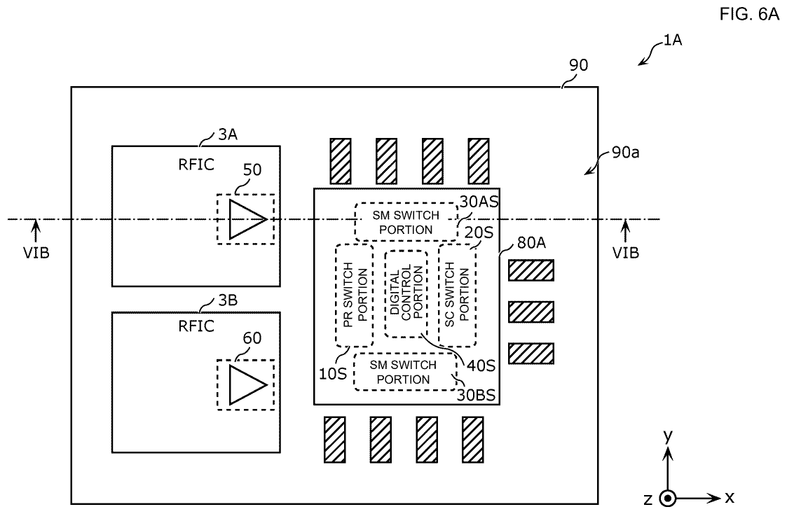

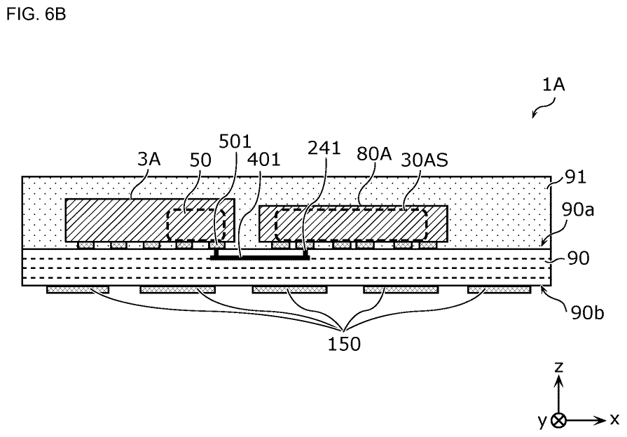

Next, a radio frequency module 1A according to Example 1 is described with reference to FIGS. 6A and 6B as a mounting example of the radio frequency circuit 1 having the above structure.

FIG. 6A is a plan view of the radio frequency module 1A according to Example 1. FIG. 6B is a cross-sectional view of the radio frequency module 1A according to Example 1. FIG. 6A is a diagram illustrating a principal surface 90a of a module laminate 90 that is viewed from the positive side of the z-axis. FIG. 6B illustrates a cross section taken along line VIB-VIB in FIG. 6A.

In FIGS. 6A and 6B, illustration is omitted for part of the wires connecting a plurality of circuit components disposed on the module laminate 90. In FIGS. 6A and 6B, illustration is omitted for a shield electrode layer that covers the surface of a resin member 91. The resin member 91 and the shield electrode layer may be omitted. In FIG. 6A, hatched blocks represent optional circuit components that may be omitted in certain exemplary aspects of the present disclosure.

As illustrated in FIG. 6A, the radio frequency module 1A includes the module laminate 90, an integrated circuit 80A, and RFICs 3A and 3B.

The module laminate 90 has principal surfaces 90a (e.g., a first principal surface) and 90b (e.g., a second principal surface) that face each other. A ground plane etc. are formed inside the module laminate 90 and on the principal surface 90a. In FIG. 6A, the module laminate 90 has a rectangular shape in plan view, but the shape of the module laminate 90 is not to be construed as limited to this configuration.

Examples of the module laminate 90 include a low temperature co-fired ceramics (LTCC) board or a high temperature co-fired ceramics (HTCC) board having a laminated structure of a plurality of dielectric layers, a component-embedded board, a board including a redistribution layer (RDL), and a printed circuit board. The module laminate 90 is not to be construed as limited to these exemplary aspects.

The resin member 91 is disposed on the principal surface 90a, covers part of the plurality of circuit components and the principal surface 90a, and is configured for securing reliability in terms of the mechanical strength, moisture resistance, and the like of the plurality of circuit components.

The integrated circuit 80A is an example of a first integrated circuit and is one of the integrated circuits forming the tracker circuit 2. The integrated circuit 80A is disposed on the principal surface 90a of the module laminate 90, and includes a PR switch portion 10S, an SC switch portion 20S, SM switch portions 30AS and 30BS, a digital control portion 40S, and the output terminals 241 and 242. The PR switch portion 10S includes the switches S61, S62, S71, and S72 of the pre-regulator circuit 10 of the radio frequency circuit 1. The SC switch portion 20S includes the switches S11 to S14, S21 to S24, S31 to S34, and S41 to S44 of the switched-capacitor circuit 20 of the radio frequency circuit 1. The SM switch portion 30AS includes the switches S51A to S54A of the supply modulator 30A of the radio frequency circuit 1. The SM switch portion 30BS includes the switches S51B to S54B of the supply modulator 30B of the radio frequency circuit 1. The digital control portion 40S includes the digital control circuit 40 of the radio frequency circuit 1.

The output terminal 241 is an example of a first output terminal and is connected to the power amplifier 50. The output terminal 242 is an example of a second output terminal and is connected to the power amplifier 60.

The integrated circuit 80A includes at least one switch included in the switched-capacitor circuit 20, at least one switch included in the supply modulator 30A, and at least one switch included in the supply modulator 30B, and may omit the PR switch portion 10S and the digital control portion 40S in exemplary aspects.

In FIG. 6A, the integrated circuit 80A has a rectangular shape in plan view of the module laminate 90, but the shape of the integrated circuit 80A is not to be construed as limited to this configuration.

The integrated circuit 80A is made of, for example, a CMOS (Complementary Metal Oxide Semiconductor), and specifically, may be manufactured by an SOI (Silicon on Insulator) process. The integrated circuit 80A is not to be construed as limited to the CMOS.

The radio frequency module 1A further includes the capacitor C61 (not illustrated) and the power inductor L71 (not illustrated) included in the pre-regulator circuit 10, and the capacitors C11 to C16 and the capacitors C10 to C40 included in the switched-capacitor circuit 20.

The capacitor C61, the power inductor L71, the capacitors C11 to C16, and the capacitors C10 to C40 are disposed on the principal surface 90a. The power inductor L71 may be disposed outside the radio frequency module 1A.

In an exemplary aspect, the capacitor C61, the capacitors C11 to C16, and the capacitors C10 to C40 are mounted as chip capacitors and can be implemented as a surface mount device (SMD) forming a capacitor. It is noted that the mounting of the plurality of capacitors is not to be construed as limited to the mounting as the chip capacitors. For example, part or all of the plurality of capacitors may be included in an integrated passive device (IPD), or may be included in the integrated circuit 80A.

At least one of the integrated circuit 80A, the capacitor C61, the power inductor L71, the capacitors C11 to C16, and the capacitors C10 to C40 may be disposed inside the module laminate 90 or on the principal surface that faces the principal surface 90a.

The RFIC 3A is an example of a second integrated circuit and has the same circuit structure as the RFIC 3A of the radio frequency circuit 1. The RFIC 3A is disposed on the principal surface 90a of the module laminate 90. The RFIC 3A may include the power amplifier 50 and the phase shift circuit 52 and may omit the low-noise amplifier 51, the phase shift circuit 53, and the switch 54 in exemplary aspects.

The RFIC 3B is an example of a third integrated circuit and has the same circuit structure as the RFIC 3B of the radio frequency circuit 1. The RFIC 3B is disposed on the principal surface 90a of the module laminate 90. The RFIC 3B may include the power amplifier 60 and the phase shift circuit 62 and may omit the low-noise amplifier 61, the phase shift circuit 63, and the switch 64 in exemplary aspects.

The RFICs 3A and 3B are each made of at least one of, for example, GaAs, SiGe, and GaN. The RFICs 3A and 3B may each be made of Si or a CMOS, and specifically, may be manufactured by an SOI process.

The radio frequency module 1A may include the integrated circuit 80A and may omit the RFICs 3A and 3B in exemplary aspects. For example, the integrated circuit 80A may be disposed on the module laminate 90, and the RFICs 3A and 3B may be disposed on a board different from the module laminate 90.

A plurality of external connection terminals 150 is disposed on the principal surface 90b. The plurality of external connection terminals 150 is electrically connected to the electronic components disposed on the principal surface 90a with via conductors etc. interposed therebetween inside the module laminate 90. The plurality of external connection terminals 150 may be bump electrodes or planar electrodes, but is not to be construed as limited to these exemplary aspects. For example, the plurality of external connection terminals 150 may be solder electrodes.

With the above structure of the radio frequency module 1A, the plurality of discrete voltages to be supplied to the power amplifiers 50 and 60 is generated by the same switched-capacitor circuit 20. The switches of the tracker circuit 2 are integrated into the integrated circuit 80A. Thus, the radio frequency module 1A including the tracker circuit 2 can be downsized.

In the radio frequency module 1A according to this example, the integrated circuit 80A is disposed to adjoin the RFIC 3A and is disposed to adjoin the RFIC 3B.

Since the integrated circuit 80A is disposed to adjoin the RFICs 3A and 3B, the radio frequency module 1A can be downsized. As illustrated in FIG. 6B, a wire 401 connecting the output terminal 241 of the integrated circuit 80A and the input terminal 501 of the RFIC 3A can be shortened. Although illustration is omitted, a wire connecting the output terminal 242 of the integrated circuit 80A and the input terminal 502 of the RFIC 3B can be shortened. Thus, ringing of the power supply voltages to be supplied from the tracker circuit 2 to the power amplifiers 50 and 60, etc. can be suppressed to achieve stability. Therefore, the efficiency of the tracker circuit 2 can be improved.

### [1.5 Mounting Example of Radio Frequency Module 1B According to Example 2]

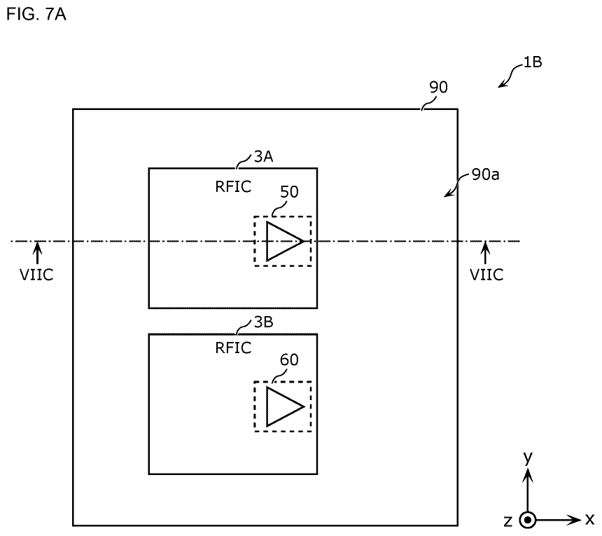

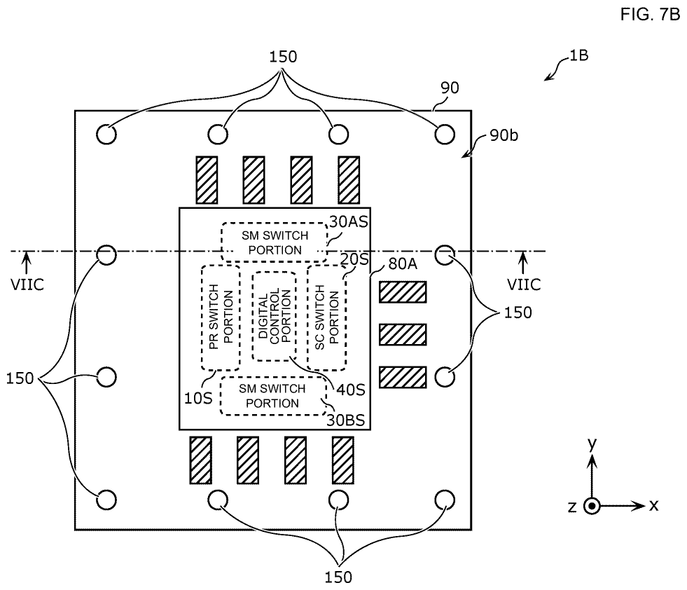

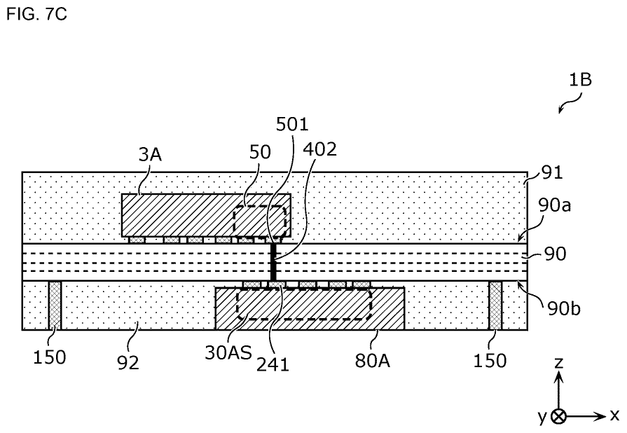

Next, a radio frequency module 1B according to Example 2 is described with reference to FIGS. 7A to 7C as a mounting example of the radio frequency circuit 1.

FIGS. 7A and 7B are plan views of the radio frequency module 1B according to Example 2. FIG. 7C is a cross-sectional view of the radio frequency module 1B according to Example 2. FIG. 7A is a diagram illustrating the principal surface 90a of the module laminate 90 that is viewed from the positive side of the z-axis. FIG. 7B is a see-through diagram of the principal surface 90b of the module laminate 90 that is viewed from the positive side of the z-axis. FIG. 7C illustrates a cross section taken along line VIIC-VIIC in FIGS. 7A and 7B.

In FIGS. 7A to 7C, illustration is omitted for part of the wires connecting the plurality of circuit components disposed on the module laminate 90. In FIGS. 7A to 7C, illustration is omitted for shield electrode layers that cover the surfaces of resin members 91 and 92. The resin members 91 and 92 and the shield electrode layers may be omitted. In FIG. 7B, hatched blocks represent optional circuit components that may be omitted in certain exemplary aspects of the present disclosure.

As illustrated in FIGS. 7A and 7B, the radio frequency module 1B includes the module laminate 90, the integrated circuit 80A, and the RFICs 3A and 3B. The radio frequency module 1B according to this example is different from the radio frequency module 1A according to Example 1 in that the integrated circuit 80A and the RFICs 3A and 3B are disposed separately on both the principal surfaces of the module laminate 90. Regarding the radio frequency module 1B according to this example, the same structure as that of the radio frequency module 1A according to Example 1 is not described below, and different structures are mainly described.

The module laminate 90 has the principal surfaces 90a (e.g., a first principal surface) and 90b (e.g., a second principal surface) that face each other.

The RFICs 3A and 3B are disposed on the principal surface 90a. The integrated circuit 80A is disposed on the principal surface 90b.

The plurality of external connection terminals 150 is disposed on the principal surface 90b. The plurality of external connection terminals 150 is electrically connected to the electronic components disposed on the principal surface 90a and the electronic components disposed on the principal surface 90b with via conductors etc. interposed therebetween inside the module laminate 90. The plurality of external connection terminals 150 may be bump electrodes or planar electrodes, but is not to be construed as limited to these exemplary aspects. For example, the plurality of external connection terminals 150 may be solder electrodes in an alternative aspect.

In plan view of the principal surfaces 90a and 90b, the first amplification transistor of the power amplifier 50 overlaps the integrated circuit 80A at least in part, and the second amplification transistor of the power amplifier 60 overlaps the integrated circuit 80A at least in part.

Since the integrated circuit 80A and the RFICs 3A and 3B are disposed separately on both the principal surfaces of the module laminate 90, the radio frequency module 1B can be downsized. As illustrated in FIG. 7C, a wire 402 connecting the output terminal 241 of the integrated circuit 80A and the input terminal 501 of the RFIC 3A can be shortened. Although illustration is omitted, a wire connecting the output terminal 242 of the integrated circuit 80A and the input terminal 502 of the RFIC 3B can be shortened. Thus, ringing of the power supply voltages to be supplied from the tracker circuit 2 to the power amplifiers 50 and 60, etc. can be suppressed to achieve stability. Therefore, the efficiency of the tracker circuit 2 can be improved.

### 1.6 Technical Effects

As described above, the radio frequency circuit 1 according to this embodiment includes the power amplifier 50 connected to the antenna 200V, the power amplifier 60 connected to the antenna 200H, the switched-capacitor circuit 20 configured to generate the plurality of discrete voltages based on the input voltage, the supply modulator 30A configured to selectively output at least one of the plurality of discrete voltages to the power amplifier 50, and the supply modulator 30B configured to selectively output at least one of the plurality of discrete voltages to the power amplifier 60.

In the above, the plurality of discrete voltages to be supplied to the power amplifiers 50 and 60 is generated by the same switched-capacitor circuit 20. Thus, the tracker circuit 2 can be downsized, thereby providing a small-size radio frequency circuit 1 including the power amplification system in the ET mode.

For example, in the radio frequency circuit 1, the supply modulator 30A is configured to select at least one of the plurality of discrete voltages in accordance with the first parallel data signal (DCL1), and the supply modulator 30B is configured to select at least one of the plurality of discrete voltages in accordance with the second parallel data signal (DCL2) different from the first parallel data signal.

In the above, the power supply voltages to be supplied to the power amplifiers 50 and 60 can be optimized. Therefore, the distortion characteristics of the power amplifiers 50 and 60 can be optimized. In an exemplary aspect, when the power amplifiers 50 and 60 are operated by MIMO (Multiple-Input and Multiple-Output), the parameters of DPD circuits disposed upstream of the power amplifiers 50 and 60 can be set individually. Therefore, the communication throughput can be improved.

For example, in the radio frequency circuit 1, the supply modulator 30A is configured to select at least one of the plurality of discrete voltages in accordance with the first parallel data signal (DCL1), and the supply modulator 30B is configured to select at least one of the plurality of discrete voltages in accordance with the first parallel data signal (DCL1).

In the above, the same reference signal is transmitted from the antennas 200V and 200H, and the optimum communication state can therefore be obtained. Thus, the communication coverage can be improved.

The radio frequency module 1A according to Example 1 (and the radio frequency module 1B according to Example 2) includes the module laminate 90, and the integrated circuit 80A disposed on the module laminate 90. The integrated circuit 80A includes at least one switch included in the switched-capacitor circuit 20, at least one switch included in the supply modulator 30A, and at least one switch included in the supply modulator 30B. The switched-capacitor circuit 20 is configured to generate the plurality of discrete voltages based on the input voltage and output the plurality of generated discrete voltages to the supply modulators 30A and 30B. The output terminal 241 of the supply modulator 30A included in the integrated circuit 80A is connected to the power amplifier 50 connected to the antenna 200V. The output terminal 242 of the supply modulator 30B included in the integrated circuit 80A is connected to the power amplifier 60 connected to the antenna 200H.

In the above, the plurality of discrete voltages to be supplied to the power amplifiers 50 and 60 is generated by the same switched-capacitor circuit 20. The switches of the tracker circuit 2 are integrated into the integrated circuit 80A. Thus, the radio frequency module 1A (and 1B) including the tracker circuit 2 can be downsized.

For example, the radio frequency module 1A (and the radio frequency module 1B) further includes the RFICs 3A and 3B disposed on the module laminate 90. The RFIC 3 A includes the power amplifier 50, and the phase shift circuit 52 connected to the input end of the power amplifier 50. The RFIC 3B includes the power amplifier 60, and the phase shift circuit 62 connected to the input end of the power amplifier 60.

In the above, the integrated circuit 80A and the RFICs 3A and 3B are disposed on the single module laminate 90. Thus, the radio frequency module 1A (and 1B) including the power amplifiers 50 and 60 can be downsized.

For example, in the radio frequency module 1A, the integrated circuit 80A and the RFICs 3A and 3B are disposed on the principal surface 90a of the module laminate 90. The integrated circuit 80A is disposed to adjoin the RFIC 3A and is disposed to adjoin the RFIC 3B.

In the above, the integrated circuit 80A is disposed to adjoin the RFICs 3A and 3B. Therefore, the radio frequency module 1A can be downsized. The wire 401 connecting the output terminal 241 of the integrated circuit 80A and the input terminal 501 of the RFIC 3A can be shortened. The wire connecting the output terminal 242 of the integrated circuit 80A and the input terminal 502 of the RFIC 3B can be shortened. Thus, ringing of the power supply voltages to be supplied from the tracker circuit 2 to the power amplifiers 50 and 60, etc. can be suppressed to achieve stability. Therefore, the efficiency of the tracker circuit 2 can be improved.

For example, in the radio frequency module 1B, the module laminate 90 has the principal surfaces 90a and 90b that face each other. The RFICs 3A and 3B are disposed on the principal surface 90a. The integrated circuit 80A is disposed on the principal surface 90b. In plan view of the principal surfaces 90a and 90b, the amplification transistor of the power amplifier 50 overlaps the integrated circuit 80A at least in part, and the amplification transistor of the power amplifier 60 overlaps the integrated circuit 80A at least in part.

In the above, the integrated circuit 80A and the RFICs 3A and 3B are disposed separately on both the principal surfaces of the module laminate 90. Therefore, the radio frequency module 1B can be downsized. The wire 402 connecting the output terminal 241 of the integrated circuit 80A and the input terminal 501 of the RFIC 3A can be shortened. The wire connecting the output terminal 242 of the integrated circuit 80A and the input terminal 502 of the RFIC 3B can be shortened. Thus, ringing of the power supply voltages to be supplied from the tracker circuit 2 to the power amplifiers 50 and 60, etc. can be suppressed to achieve stability. Therefore, the efficiency of the tracker circuit 2 can be improved.

The radio frequency signal transmission method according to this embodiment includes generating the plurality of discrete voltages based on the input voltage, selectively supplying at least one of the plurality of discrete voltages to the power amplifier 50 based on the envelope signal of the first radio frequency signal, selectively supplying at least one of the plurality of discrete voltages to the power amplifier 60 based on the envelope signal of the second radio frequency signal, amplifying the first radio frequency signal by the power amplifier 50 and radiating the vertically polarized signal, and amplifying the second radio frequency signal by the power amplifier 60 and radiating the horizontally polarized signal.

In the above, the first radio frequency signal to be output to the antenna 200V and the second radio frequency signal to be output to the antenna 200H can be amplified in the ET mode. At this time, the plurality of discrete voltages to be supplied to the power amplifier 50 that amplifies the first radio frequency signal and the power amplifier 60 that amplifies the second radio frequency signal is generated by the same switched-capacitor circuit 20. That is, the tracker circuit 2 can be downsized. Thus, a small-size radio frequency circuit 1 including the power amplification system in the ET mode can be provided.

For example, in the radio frequency signal transmission method, the timing to selectively supply at least one of the plurality of discrete voltages to the power amplifier 50 based on the envelope signal of the first radio frequency signal is the same as the timing to selectively supply at least one of the plurality of discrete voltages to the power amplifier 60 based on the envelope signal of the second radio frequency signal.

In the above, the power supply voltage to be supplied to the power amplifier 50 and the power supply voltage to be supplied to the power amplifier 60 are output from different supply modulators. Therefore, the vertically polarized signal and the horizontally polarized signal can be radiated with high efficiency and high accuracy.

### Second Exemplary Embodiment

The radio frequency circuit 1 according to the first embodiment has the structure in which the radio frequency signals in one radio frequency band are output to the vertical polarization antenna and the horizontal polarization antenna. A radio frequency circuit 6 according to this embodiment has a structure in which radio frequency signals in two radio frequency bands are output to vertical polarization antennas and horizontal polarization antennas.

### [2.1 Circuit Structure of Radio Frequency Circuit 6]

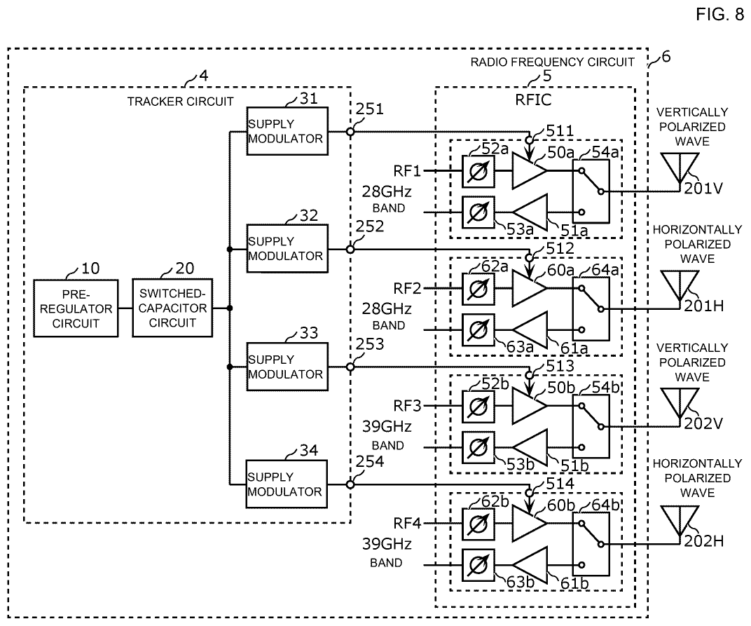

FIG. 8 is a circuit structure diagram of the radio frequency circuit 6 according to the second embodiment. As illustrated in FIG. 8, the radio frequency circuit 6 includes a tracker circuit 4 and an RFIC 5.

The RFIC 5 is an example of the signal processing circuit, and includes phase shift circuits 52a, 52b, 53a, 53b, 62a, 62b, 63a, and 63b, power amplifiers 50a, 50b, 60a, and 60b, low-noise amplifiers 51a, 51b, 61a, and 61b, switches 54a, 54b, 64a, and 64b, and input terminals 511, 512, 513, and 514. The RFIC 5 is configured to output signals in a first radio frequency band to antennas 201V and 201H, and output signals in a second radio frequency band on a higher frequency side relative to the first radio frequency band to antennas 202V and 202H.

The RFIC 5 may include a first RFIC including the phase shift circuit 52a and the power amplifier 50a, a second RFIC including the phase shift circuit 62a and the power amplifier 60a, a third RFIC including the phase shift circuit 52b and the power amplifier 50b, and a fourth RFIC including the phase shift circuit 62b and the power amplifier 60b.

The phase shift circuit 52a is connected to an input end of the power amplifier 50a and adjusts the phase of a transmission signal in the first radio frequency band. The phase shift circuit 53a adjusts the phase of a reception signal in the first radio frequency band that is output from the low-noise amplifier 51a. The phase shift circuit 62a is connected to an input end of the power amplifier 60a and adjusts the phase of a transmission signal in the first radio frequency band. The phase shift circuit 63a adjusts the phase of a reception signal in the first radio frequency band that is output from the low-noise amplifier 61a.

The phase shift circuit 52b is connected to an input end of the power amplifier 50b and adjusts the phase of a transmission signal in the second radio frequency band. The phase shift circuit 53b adjusts the phase of a reception signal in the second radio frequency band that is output from the low-noise amplifier 51b. The phase shift circuit 62b is connected to an input end of the power amplifier 60b and adjusts the phase of a transmission signal in the second radio frequency band. The phase shift circuit 63b adjusts the phase of a reception signal in the second radio frequency band that is output from the low-noise amplifier 61b.

The power amplifier 50a is an example of the first power amplifier, is connected to the antenna 201V via the switch 54a and amplifies the transmission signal in the first radio frequency band that is output from the phase shift circuit 52a. The low-noise amplifier 51a amplifies the reception signal in the first radio frequency band that is output from the antenna 201V. The power amplifier 50a includes the first amplification transistor. The first amplification transistor is disposed in series on a path connecting the phase shift circuit 52a and the switch 54a.

The power amplifier 60a is an example of the second power amplifier, is connected to the antenna 201H via the switch 64a and amplifies the transmission signal in the first radio frequency band that is output from the phase shift circuit 62a. The low-noise amplifier 61a amplifies the reception signal in the first radio frequency band that is output from the antenna 201H. The power amplifier 60a includes the second amplification transistor. The second amplification transistor is disposed in series on a path connecting the phase shift circuit 62a and the switch 64a.

The power amplifier 50b is an example of a third power amplifier, is connected to the antenna 202V via the switch 54b and amplifies the transmission signal in the second radio frequency band that is output from the phase shift circuit 52b. The low-noise amplifier 51b amplifies the reception signal in the second radio frequency band that is output from the antenna 202V. The power amplifier 50b includes a third amplification transistor. The third amplification transistor is disposed in series on a path connecting the phase shift circuit 52b and the switch 54b.

The power amplifier 60b is an example of a fourth power amplifier, is connected to the antenna 202H via the switch 64b and amplifies the transmission signal in the second radio frequency band that is output from the phase shift circuit 62b. The low-noise amplifier 61b amplifies the reception signal in the second radio frequency band that is output from the antenna 202H. The power amplifier 60b includes a fourth amplification transistor. The fourth amplification transistor is disposed in series on a path connecting the phase shift circuit 62b and the switch 64b.

The switch 54a switches the connection between the antenna 201V and an output end of the power amplifier 50a and the connection between the antenna 201V and an input end of the low-noise amplifier 51a. The switch 64a switches the connection between the antenna 201H and an output end of the power amplifier 60a and the connection between the antenna 201H and an input end of the low-noise amplifier 61a.

The switch 54b switches the connection between the antenna 202V and an output end of the power amplifier 50b and the connection between the antenna 202V and an input end of the low-noise amplifier 51b. The switch 64b switches the connection between the antenna 202H and an output end of the power amplifier 60b and the connection between the antenna 202H an input end of the low-noise amplifier 61b.

The input terminal 511 is a terminal that is connected to the power amplifier 50a and receives the power supply voltage V_{ET1} supplied from the tracker circuit 4. The input terminal 512 is a terminal that is connected to the power amplifier 60a and receives the power supply voltage V_{ET2} supplied from the tracker circuit 4. The input terminal 513 is a terminal that is connected to the power amplifier 50b and receives a power supply voltage V_{ET3} supplied from the tracker circuit 4. The input terminal 514 is a terminal that is connected to the power amplifier 60b and receives a power supply voltage V_{ET4} supplied from the tracker circuit 4.

The first radio frequency band and the second radio frequency band are each a millimeter wave band or a sub-terahertz band. The first radio frequency band is, for example, a 28-GHz band, and the second radio frequency band is, for example, a 39-GHz band.

The tracker circuit 4 generates supply voltages to the power amplifiers 50a and 60a that amplify signals in the first radio frequency band, generates supply voltages to the power amplifiers 50b and 60b that amplify signals in the second radio frequency band, and includes at least one integrated circuit. Specifically, the tracker circuit 4 supplies variable voltages in the digital ET mode or the SPT mode to the power amplifiers based on envelope signals supplied from the BBIC.

The antenna 201V is an example of the first vertical polarization antenna, and vertically polarizes and radiates the transmission signal in the first radio frequency band that is output from the radio frequency circuit 6. The antenna 201V outputs, to the radio frequency circuit 6, a received vertically polarized signal in the first radio frequency band. The antenna 201H is an example of the first horizontal polarization antenna, and horizontally polarizes and radiates the transmission signal in the first radio frequency band that is output from the radio frequency circuit 6. The antenna 201H outputs, to the radio frequency circuit 6, a received horizontally polarized signal in the first radio frequency band.

The antenna 202V is an example of a second vertical polarization antenna, and vertically polarizes and radiates the transmission signal in the second radio frequency band that is output from the radio frequency circuit 6. The antenna 202V outputs, to the radio frequency circuit 6, a received vertically polarized signal in the second radio frequency band. The antenna 202H is an example of a second horizontal polarization antenna, and horizontally polarizes and radiates the transmission signal in the second radio frequency band that is output from the radio frequency circuit 6. The antenna 202H outputs, to the radio frequency circuit 6, a received horizontally polarized signal in the second radio frequency band.

### [2.2 Circuit Structure of Tracker Circuit 4]

The tracker circuit 4 includes a pre-regulator circuit 10, a switched-capacitor circuit 20, supply modulators 31, 32, 33, and 34, a digital control circuit (not illustrated), and output terminals 251, 252, 253, and 254.

The pre-regulator circuit 10 has a circuit structure similar to that of the pre-regulator circuit 10 according to the first embodiment. The switched-capacitor circuit 20 has a circuit structure similar to that of the switched-capacitor circuit 20 according to the first embodiment.

The supply modulator 31 is an example of the first supply modulator and is configured to select at least one of the plurality of discrete voltages generated by the switched-capacitor circuit 20 and output it to the power amplifier 50a. The supply modulator 32 is an example of the second supply modulator and is configured to select at least one of the plurality of discrete voltages generated by the switched-capacitor circuit 20 and output it to the power amplifier 60a.

The supply modulator 33 is an example of a third supply modulator and is configured to select at least one of the plurality of discrete voltages generated by the switched-capacitor circuit 20 and output it to the power amplifier 50b. The supply modulator 34 is an example of a fourth supply modulator and is configured to select at least one of the plurality of discrete voltages generated by the switched-capacitor circuit 20 and output it to the power amplifier 60b.

The supply modulators 31 to 34 each have a circuit structure similar to that of the supply modulator 30A according to the first embodiment.

The digital control circuit can control the pre-regulator circuit 10, the switched-capacitor circuit 20, and the supply modulators 31 to 34 based on digital control signals from the BBIC.

The tracker circuit 4 may omit part of the pre-regulator circuit 10 and the digital control circuit in exemplary aspects.

With the above structure, the tracker circuit 4 can supply the power supply voltage V_{ET1} from the supply modulator 31 to the power amplifier 50a, supply the power supply voltage V_{ET2} from the supply modulator 32 to the power amplifier 60a, supply the power supply voltage V_{ET3} from the supply modulator 33 to the power amplifier 50b, and supply the power supply voltage V_{ET4} from the supply modulator 34 to the power amplifier 60b.

With the above structure of the radio frequency circuit 6, the plurality of discrete voltages to be supplied to the power amplifiers 50a, 50b, 60a, and 60b is generated by the same switched-capacitor circuit 20. Thus, the tracker circuit 4 can be downsized, thereby providing a small-size radio frequency circuit 6 including the power amplification system in the ET mode.

The supply modulator 31 may select at least one of the plurality of discrete voltages in accordance with a DCL signal (DCL1: first parallel data signal). The supply modulator 32 may select at least one of the plurality of discrete voltages in accordance with a DCL signal (DCL2: second parallel data signal). The supply modulator 33 may select at least one of the plurality of discrete voltages in accordance with a DCL signal (DCL3: third parallel data signal). The supply modulator 34 may select at least one of the plurality of discrete voltages in accordance with a DCL signal (DCL4: fourth parallel data signal).

That is, the supply modulators 31 to 34 can supply the power supply voltages individually to the power amplifiers 50a, 50b, 60a, and 60b by being controlled based on the different DCL signals (DCL1 to DCL4). Thus, the power supply voltages to be supplied to the power amplifiers 50a, 50b, 60a, and 60b can be optimized. Therefore, the distortion characteristics of the power amplifiers 50a, 50b, 60a, and 60b can be optimized. In an exemplary aspect, when the power amplifiers 50a, 50b, 60a, and 60b are operated by MIMO, the parameters of DPD circuits disposed upstream of the power amplifiers 50a, 50b, 60a, and 60b can be set individually. Therefore, the communication throughput can be improved.

The supply modulators 31 and 32 may be controlled based on the same DCL signal (e.g., DCL1), and the supply modulators 33 and 34 may be controlled based on the same DCL signal (e.g., DCL3). In this case, the same reference signal is transmitted from the antennas 201V and 201H, and the same reference signal is transmitted from the antennas 202V and 202H. Therefore, the optimum communication state can be obtained. Thus, the communication coverage can be improved.

### [2.3 Mounting Example of Radio Frequency Module 1C According to Example 3]

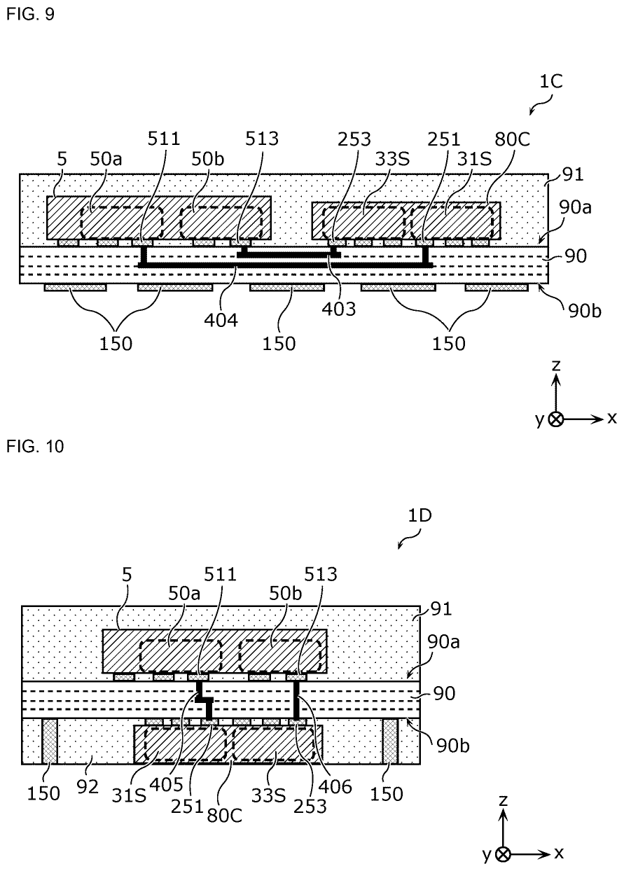

Next, a radio frequency module 1C according to Example 3 is described with reference to FIG. 9 as a mounting example of the radio frequency circuit 6.

FIG. 9 is a cross-sectional view of the radio frequency module 1C according to Example 3. In FIG. 9, illustration is omitted for part of the wires connecting a plurality of circuit components disposed on the module laminate 90. In FIG. 9, illustration is omitted for a shield electrode layer that covers the surface of the resin member 91. The resin member 91 and the shield electrode layer may be omitted.

As illustrated in FIG. 9, the radio frequency module 1C includes the module laminate 90, an integrated circuit 80C, and an RFIC 5. The radio frequency module 1C according to this example is different from the radio frequency module 1A according to Example 1 only in terms of the structures of the integrated circuit 80C and the RFIC 5. Regarding the radio frequency module 1C according to this example, the same structure as that of the radio frequency module 1A according to Example 1 is not described below, and different structures are mainly described.

It is noted that the integrated circuit 80C is an example of the first integrated circuit and is one of the integrated circuits forming the tracker circuit 4. The integrated circuit 80C is disposed on the principal surface 90a of the module laminate 90, and includes the PR switch portion 10S, the SC switch portion 20S, SM switch portions 31S, 32S, 33S, and 34S, a digital control portion, and the output terminals 251 to 254. The PR switch portion 10S includes the switches S61, S62, S71, and S72 of the pre-regulator circuit 10 of the radio frequency circuit 6. The SC switch portion 20S includes the switches S11 to S14, S21 to S24, S31 to S34, and S41 to S44 of the switched-capacitor circuit 20 of the radio frequency circuit 6. The SM switch portion 31S includes the switches of the supply modulator 31 of the radio frequency circuit 6. The SM switch portion 32S includes the switches of the supply modulator 32 of the radio frequency circuit 6. The SM switch portion 33S includes the switches of the supply modulator 33 of the radio frequency circuit 6. The SM switch portion 34S includes the switches of the supply modulator 34 of the radio frequency circuit 6. The digital control portion includes the digital control circuit of the radio frequency circuit 6.

The output terminal 251 is an example of the first output terminal and is connected to the power amplifier 50a. The output terminal 252 is an example of the second output terminal and is connected to the power amplifier 60a. The output terminal 253 is an example of a third output terminal and is connected to the power amplifier 50b. The output terminal 254 is an example of a fourth output terminal and is connected to the power amplifier 60b.

The integrated circuit 80C includes at least one switch included in the switched-capacitor circuit 20 and at least one switch included in each of the supply modulators 31 to 34, and may omit the PR switch portion 10S and the digital control portion in exemplary aspects.

The integrated circuit 80C is made of, for example, a CMOS, and specifically, may be manufactured by an SOI process. The integrated circuit 80C is not to be construed as limited to the CMOS.

Although illustration is omitted in FIG. 9, the radio frequency module 1C further includes the capacitor C61 and the power inductor L71 included in the pre-regulator circuit 10, and the capacitors C11 to C16 and the capacitors C10 to C40 included in the switched-capacitor circuit 20.

The capacitor C61, the power inductor L71, the capacitors C11 to C16, and the capacitors C10 to C40 are disposed on the principal surface 90a. The power inductor L71 may be disposed outside the radio frequency module 1C.

At least one of the integrated circuit 80C, the capacitor C61, the power inductor L71, the capacitors C11 to C16, and the capacitors C10 to C40 may be disposed inside the module laminate 90 or on the principal surface that faces the principal surface 90a.

The RFIC 5 is an example of a fourth integrated circuit and has the same circuit structure as the RFIC 5 of the radio frequency circuit 6. The RFIC 5 is disposed on the principal surface 90a of the module laminate 90. The RFIC 5 may omit one or all of the low-noise amplifiers 51a, 51b, 61a, and 61b, the phase shift circuits 53a, 53b, 63a, and 63b, and the switches 54a, 54b, 64a, and 64b in exemplary aspects.

The RFIC 5 is made of at least one of, for example, GaAs, SiGe, and GaN. The RFIC 5 may be made of Si or a CMOS, and specifically, may be manufactured by an SOI process.

With the above structure of the radio frequency module 1C, the plurality of discrete voltages to be supplied to the power amplifiers 50a, 50b, 60a, and 60b is generated by the same switched-capacitor circuit 20. The switches of the tracker circuit 4 are integrated into the integrated circuit 80C. Thus, the radio frequency module 1C including the tracker circuit 4 can be downsized.

In the radio frequency module 1C according to this example, the integrated circuit 80C is disposed to adjoin the RFIC 5.

Since the integrated circuit 80C is disposed to adjoin the RFIC 5, the radio frequency module 1C can be downsized. As illustrated in FIG. 9, a wire 404 connecting the output terminal 251 of the integrated circuit 80C and the input terminal 511 of the RFIC 5 can be shortened, and a wire 403 connecting the output terminal 253 of the integrated circuit 80C and the input terminal 513 of the RFIC 5 can be shortened. Although illustration is omitted, a wire connecting the output terminal 252 of the integrated circuit 80C and the input terminal 512 of the RFIC 5 can be shortened, and a wire connecting the output terminal 254 of the integrated circuit 80C and the input terminal 514 of the RFIC 5 can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

The wire 403 may be shorter than the wire 404. Therefore, it is possible to further suppress, for example, ringing of the power supply voltage V_{ET3} to be supplied to the power amplifier 50b that amplifies the radio frequency signal in the second radio frequency band on the higher frequency side relative to the first radio frequency band.

### [2.4 Mounting Example of Radio Frequency Module 1D According to Example 4]

Next, a radio frequency module 1D according to Example 4 is described with reference to FIG. 10 as a mounting example of the radio frequency circuit 6.

FIG. 10 is a cross-sectional view of the radio frequency module 1D according to Example 4. In FIG. 10, illustration is omitted for part of the wires connecting the plurality of circuit components disposed on the module laminate 90. In FIG. 10, illustration is omitted for shield electrode layers that cover the surfaces of the resin members 91 and 92. The resin members 91 and 92 and the shield electrode layers may be omitted.

As illustrated in FIG. 10, the radio frequency module 1D includes the module laminate 90, the integrated circuit 80C, and the RFIC 5. The radio frequency module 1D according to this example is different from the radio frequency module 1C according to Example 3 in that the integrated circuit 80C and the RFIC 5 are disposed separately on both the principal surfaces of the module laminate 90. Regarding the radio frequency module 1D according to this example, the same structure as that of the radio frequency module 1C according to Example 3 is not described below, and different structures are mainly described.

The module laminate 90 has the principal surfaces 90a (e.g., a first principal surface) and 90b (e.g., a second principal surface) that face each other.

The RFIC 5 is disposed on the principal surface 90a. The integrated circuit 80C is disposed on the principal surface 90b.

In plan view of the principal surfaces 90a and 90b, the first amplification transistor of the power amplifier 50a overlaps the integrated circuit 80C at least in part, the second amplification transistor of the power amplifier 60a overlaps the integrated circuit 80C at least in part, the third amplification transistor of the power amplifier 50b overlaps the integrated circuit 80C at least in part, and the fourth amplification transistor of the power amplifier 60b overlaps the integrated circuit 80C at least in part.

Since the integrated circuit 80C and the RFIC 5 are disposed separately on both the principal surfaces of the module laminate 90, the radio frequency module 1D can be downsized. As illustrated in FIG. 10, a wire 405 connecting the output terminal 251 of the integrated circuit 80C and the input terminal 511 of the RFIC 5 can be shortened, and a wire 406 connecting the output terminal 253 of the integrated circuit 80C and the input terminal 513 of the RFIC 5 can be shortened. Although illustration is omitted, a wire connecting the output terminal 252 of the integrated circuit 80C and the input terminal 512 of the RFIC 5 can be shortened, and a wire connecting the output terminal 254 of the integrated circuit 80C and the input terminal 514 of the RFIC 5 can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

### [2.5 Circuit Structure of Radio Frequency Circuit 7 According to Modification 1]

Next, the circuit structure of a radio frequency circuit 7 according to Modification 1 of this embodiment is described.

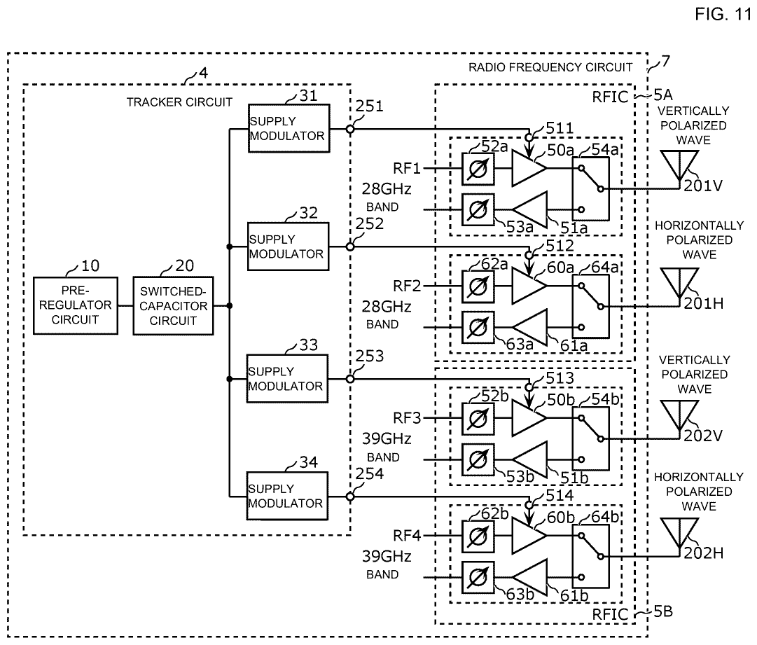

FIG. 11 is a circuit structure diagram of the radio frequency circuit 7 according to Modification 1 of the second embodiment. The radio frequency circuit 7 includes the tracker circuit 4 and RFICs 5A and 5B. The radio frequency circuit 7 according to this modification is different from the radio frequency circuit 6 according to the second embodiment in that the RFIC 5 is divided into the RFICs 5A and 5B. Regarding the radio frequency circuit 7 according to this modification, the same structure as that of the radio frequency circuit 6 according to the second embodiment is not described below, and different structures are mainly described.

The RFIC 5A is an example of a fifth integrated circuit, includes the phase shift circuits 52a, 53a, 62a, and 63a, the power amplifiers 50a and 60a, the low-noise amplifiers 51a and 61a, the switches 54a and 64a, and the input terminals 511 and 512, and is configured to output signals in the first radio frequency band to the antennas 201V and 201H.

The RFIC 5B is an example of a sixth integrated circuit, includes the phase shift circuits 52b, 53b, 62b, and 63b, the power amplifiers 50b and 60b, the low-noise amplifiers 51b and 61b, the switches 54b and 64b, and the input terminals 513 and 514, and is configured to output signals in the second radio frequency band on the higher frequency side relative to the first radio frequency band to the antennas 202V and 202H.

With the above structure of the radio frequency circuit 7, the plurality of discrete voltages to be supplied to the power amplifiers 50a, 50b, 60a, and 60b is generated by the same switched-capacitor circuit 20. Thus, the tracker circuit 4 can be downsized, thereby providing a small-size radio frequency circuit 7 including the power amplification system in the ET mode.

### [2.6 Mounting Example of Radio Frequency Module 1E According to Example 5]

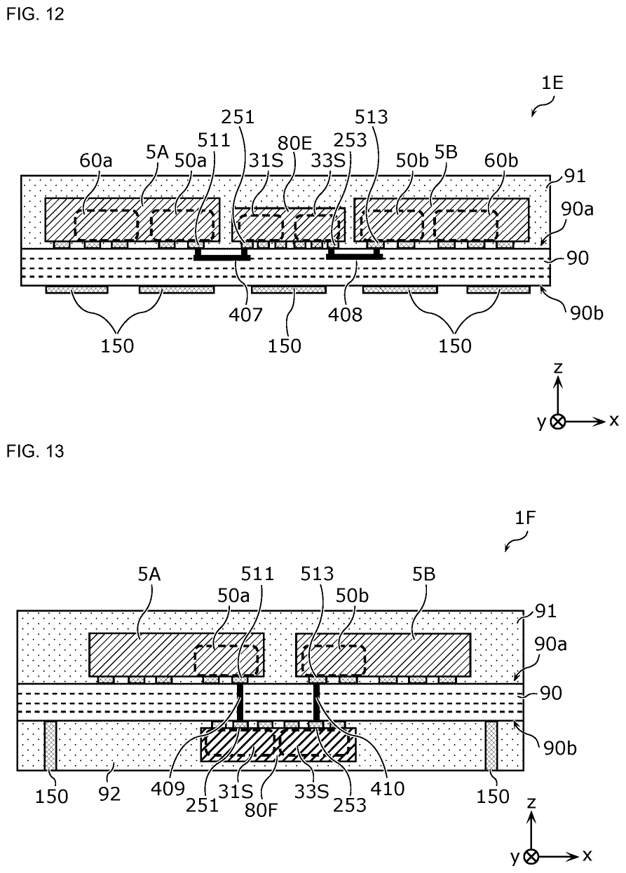

Next, a radio frequency module 1E according to Example 5 is described with reference to FIG. 12 as a mounting example of the radio frequency circuit 7.

FIG. 12 is a cross-sectional view of the radio frequency module 1E according to Example 5. In FIG. 12, illustration is omitted for part of the wires connecting a plurality of circuit components disposed on the module laminate 90. In FIG. 12, illustration is omitted for a shield electrode layer that covers the surface of the resin member 91. The resin member 91 and the shield electrode layer may be omitted.

As illustrated in FIG. 12, the radio frequency module 1E includes the module laminate 90, an integrated circuit 80E, and RFICs 5A and 5B. The radio frequency module 1E according to this example is different from the radio frequency module 1C according to Example 3 in terms of the structure in which the integrated circuit 80E is disposed between the RFIC 5A and the RFIC 5B. Regarding the radio frequency module 1E according to this example, the same structure as that of the radio frequency module 1C according to Example 3 is not described below, and different structures are mainly described.

It is noted that the integrated circuit 80E is an example of the first integrated circuit and is one of the integrated circuits forming the tracker circuit 4. The integrated circuit 80E is disposed on the principal surface 90a of the module laminate 90, and includes the PR switch portion 10S, the SC switch portion 20S, the SM switch portions 31S, 32S, 33S, and 34S, a digital control portion, and the output terminals 251 to 254. The PR switch portion 10S includes the switches S61, S62, S71, and S72 of the pre-regulator circuit 10 of the radio frequency circuit 7. The SC switch portion 20S includes the switches S11 to S14, S21 to S24, S31 to S34, and S41 to S44 of the switched-capacitor circuit 20 of the radio frequency circuit 7. The SM switch portion 31S includes the switches of the supply modulator 31 of the radio frequency circuit 7. The SM switch portion 32S includes the switches of the supply modulator 32 of the radio frequency circuit 7. The SM switch portion 33S includes the switches of the supply modulator 33 of the radio frequency circuit 7. The SM switch portion 34S includes the switches of the supply modulator 34 of the radio frequency circuit 7. The digital control portion includes the digital control circuit of the radio frequency circuit 7.

The output terminal 251 is an example of the first output terminal and is connected to the power amplifier 50a. The output terminal 252 is an example of the second output terminal and is connected to the power amplifier 60a. The output terminal 253 is an example of the third output terminal and is connected to the power amplifier 50b. The output terminal 254 is an example of the fourth output terminal and is connected to the power amplifier 60b.

The integrated circuit 80E includes at least one switch included in the switched-capacitor circuit 20 and at least one switch included in each of the supply modulators 31 to 34, and may omit the PR switch portion 10S and the digital control portion in exemplary aspects.

The integrated circuit 80E is made of, for example, a CMOS, and specifically, may be manufactured by an SOI process. The integrated circuit 80E is not to be construed as limited to the CMOS.

Although illustration is omitted in FIG. 12, the radio frequency module 1E further includes the capacitor C61 and the power inductor L71 included in the pre-regulator circuit 10, and the capacitors C11 to C16 and the capacitors C10 to C40 included in the switched-capacitor circuit 20.

The capacitor C61, the power inductor L71, the capacitors C11 to C16, and the capacitors C10 to C40 are disposed on the principal surface 90a. The power inductor L71 may be disposed outside the radio frequency module 1E.

At least one of the integrated circuit 80E, the capacitor C61, the power inductor L71, the capacitors C11 to C16, and the capacitors C10 to C40 may be disposed inside the module laminate 90 or on the principal surface that faces the principal surface 90a. The RFIC 5A is an example of the fifth integrated circuit and has the same circuit structure as the RFIC 5A of the radio frequency circuit 7. The RFIC 5A is disposed on the principal surface 90a of the module laminate 90. The RFIC 5A may omit the low-noise amplifiers 51a and 61a, the phase shift circuits 53a and 63a, and the switches 54a and 64a in exemplary aspects.

The RFIC 5B is an example of the sixth integrated circuit and has the same circuit structure as the RFIC 5B of the radio frequency circuit 7. The RFIC 5B is disposed on the principal surface 90a of the module laminate 90. The RFIC 5B may omit the low-noise amplifiers 51b and 61b, the phase shift circuits 53b and 63b, and the switches 54b and 64b in exemplary aspects.

The RFICs 5A and 5B are each made of at least one of, for example, GaAs, SiGe, and GaN. The RFICs 5A and 5B may each be made of Si or a CMOS, and specifically, may be manufactured by an SOI process.

As illustrated in FIG. 12, in plan view of the principal surface 90a, the integrated circuit 80E is disposed between the RFIC 5A and the RFIC 5B, and the integrated circuit 80E is disposed to adjoin the RFIC 5A and is disposed to adjoin the RFIC 5B.

Since the integrated circuit 80E is disposed to adjoin the RFIC 5A and the integrated circuit 80E is disposed to adjoin the RFIC 5B, the radio frequency module 1E can be downsized. As illustrated in FIG. 12, a wire 407 connecting the output terminal 251 of the integrated circuit 80E and the input terminal 511 of the RFIC 5A can be shortened, and a wire 408 connecting the output terminal 253 of the integrated circuit 80E and the input terminal 513 of the RFIC 5B can be shortened. Although illustration is omitted, a wire connecting the output terminal 252 of the integrated circuit 80E and the input terminal 512 of the RFIC 5A can be shortened, and a wire connecting the output terminal 254 of the integrated circuit 80E and the input terminal 514 of the RFIC 5B can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

### [2.7 Mounting Example of Radio Frequency Module 1F According to Example 6]

Next, a radio frequency module 1F according to Example 6 is described with reference to FIG. 13 as a mounting example of the radio frequency circuit 7.

FIG. 13 is a cross-sectional view of the radio frequency module IF according to Example 6. In FIG. 13, illustration is omitted for part of the wires connecting the plurality of circuit components disposed on the module laminate 90. In FIG. 13, illustration is omitted for shield electrode layers that cover the surfaces of the resin members 91 and 92. The resin members 91 and 92 and the shield electrode layers may be omitted.

As illustrated in FIG. 13, the radio frequency module 1F includes the module laminate 90, an integrated circuit 80F, and the RFICs 5A and 5B. The radio frequency module 1F according to this example is different from the radio frequency module 1E according to Example 5 in that the integrated circuit 80F and the RFICs 5A and 5B are disposed separately on both the principal surfaces of the module laminate 90. Regarding the radio frequency module IF according to this example, the same structure as that of the radio frequency module 1E according to Example 5 is not described below, and different structures are mainly described.

The module laminate 90 has the principal surfaces 90a (e.g., a first principal surface) and 90b (e.g., a second principal surface) that face each other.

The RFICs 5A and 5B are disposed on the principal surface 90a. The integrated circuit 80F is disposed on the principal surface 90b.

In plan view of the principal surfaces 90a and 90b, the first amplification transistor of the power amplifier 50a overlaps the integrated circuit 80F at least in part, the second amplification transistor of the power amplifier 60a overlaps the integrated circuit 80F at least in part, the third amplification transistor of the power amplifier 50b overlaps the integrated circuit 80F at least in part, and the fourth amplification transistor of the power amplifier 60b overlaps the integrated circuit 80F at least in part.

Since the integrated circuit 80F and the RFICs 5A and 5B are disposed separately on both the principal surfaces of the module laminate 90, the radio frequency module 1F can be downsized. As illustrated in FIG. 13, a wire 409 connecting the output terminal 251 of the integrated circuit 80F and the input terminal 511 of the RFIC 5A can be shortened, and a wire 410 connecting the output terminal 253 of the integrated circuit 80F and the input terminal 513 of the RFIC 5B can be shortened. Although illustration is omitted, a wire connecting the output terminal 252 of the integrated circuit 80F and the input terminal 512 of the RFIC 5A can be shortened, and a wire connecting the output terminal 254 of the integrated circuit 80F and the input terminal 514 of the RFIC 5B can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

### [2.8 Circuit Structure of Radio Frequency Circuit 7A According to Modification 2]

Next, the circuit structure of a radio frequency circuit 7A according to Modification 2 of this embodiment is described.

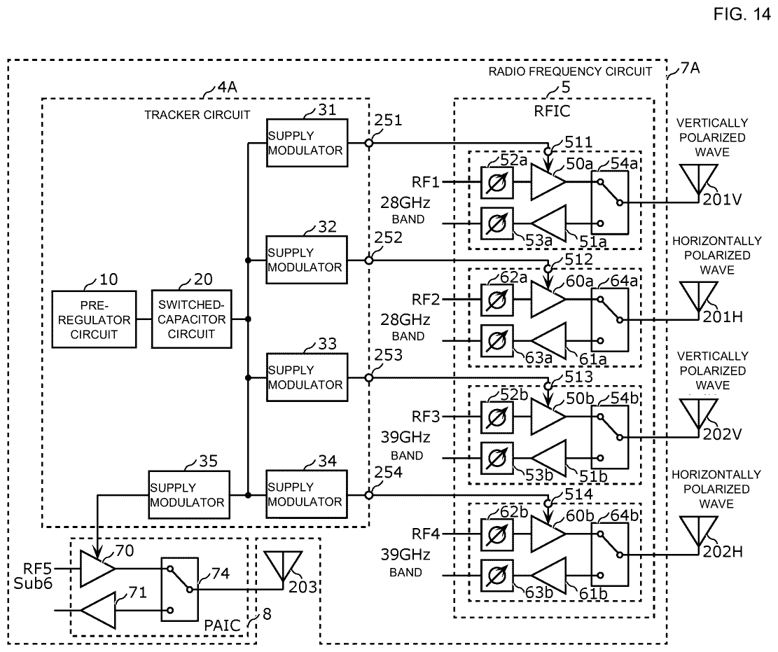

FIG. 14 is a circuit structure diagram of the radio frequency circuit 7A according to Modification 2 of the second embodiment. The radio frequency circuit 7A includes a tracker circuit 4A, the RFIC 5, and a PAIC 8. The radio frequency circuit 7A according to this modification is different from the radio frequency circuit 6 according to the second embodiment in terms of the addition of the PAIC 8 and the circuit structure of the tracker circuit 4A. Regarding the radio frequency circuit 7A according to this modification, the same structure as that of the radio frequency circuit 6 according to the second embodiment is not described below, and different structures are mainly described.

The PAIC 8 is an example of a power amplifier circuit, and includes a power amplifier 70, a low-noise amplifier 71, and a switch 74. The PAIC 8 amplifies a radio frequency signal in a frequency band belonging to a Sub-6 band (6 GHz or lower), outputs the amplified radio frequency signal in the Sub-6 band to an antenna 203, and amplifies a radio frequency signal in the Sub-6 band (6 GHz or lower) that is received by the antenna 203.

The frequency band in the Sub-6 band is a frequency band predefined by a standardizing body etc. (e.g., 3GPP® or IEEE) for communication systems constructed using the RAT.

The power amplifier 70 is an example of a fifth power amplifier, is connected to the antenna 203 via the switch 74, and amplifies the radio frequency signal in the Sub-6 band. The low-noise amplifier 71 amplifies the radio frequency signal in the Sub-6 band that is output from the antenna 203.

The switch 74 switches the connection between the antenna 203 and an output end of the power amplifier 70 and the connection between the antenna 203 and an input end of the low-noise amplifier 71.

The PAIC 8 may be an integrated circuit. The PAIC 8 includes the power amplifier 70 and may omit include the low-noise amplifier 71 and the switch 74 in exemplary aspects.

The antenna 203 is an example of a first antenna and radiates the transmission signal in the Sub-6 band that is output from the radio frequency circuit 7A. The antenna 203 outputs a received signal in the Sub-6 band to the radio frequency circuit 7A.

The tracker circuit 4A generates supply voltages to the power amplifiers 50a and 60a that amplify signals in the first radio frequency band, generates supply voltages to the power amplifiers 50b and 60b that amplify signals in the second radio frequency band, generates a supply voltage to the power amplifier 70 that amplifies signals in the Sub-6 band, and includes at least one integrated circuit. Specifically, the tracker circuit 4A supplies variable voltages in the digital ET mode or the SPT mode to the power amplifiers based on envelope signals supplied from the BBIC.

The tracker circuit 4A includes a pre-regulator circuit 10, a switched-capacitor circuit 20, supply modulators 31, 32, 33, 34, and 35, a digital control circuit (not illustrated), and output terminals 251, 252, 253, and 254.

The pre-regulator circuit 10 has a circuit structure similar to that of the pre-regulator circuit 10 according to the second embodiment. The switched-capacitor circuit 20 has a circuit structure similar to that of the switched-capacitor circuit 20 according to the second embodiment.

The supply modulator 31 is an example of the first supply modulator and has a circuit structure similar to that of the supply modulator 31 according to the second embodiment. The supply modulator 32 is an example of the second supply modulator and has a circuit structure similar to that of the supply modulator 32 according to the second embodiment. The supply modulator 33 is an example of the third supply modulator and has a circuit structure similar to that of the supply modulator 33 according to the second embodiment. The supply modulator 34 is an example of the fourth supply modulator and has a circuit structure similar to that of the supply modulator 34 according to the second embodiment. The digital control circuit has a circuit structure similar to that of the digital control circuit according to the second embodiment.

The supply modulator 35 is an example of a fifth supply modulator and is configured to select at least one of the plurality of discrete voltages generated by the switched-capacitor circuit 20 and output it to the power amplifier 70.

With the above structure of the radio frequency circuit 7A, the plurality of discrete voltages to be supplied to the power amplifiers 50a, 50b, 60a, 60b, and 70 is generated by the same switched-capacitor circuit 20. Thus, the tracker circuit 4A can be downsized, thereby providing a small-size radio frequency circuit 7A including the power amplification system in the ET mode.

### 2.9 Technical Effects

As described above, the radio frequency circuit 6 according to this embodiment includes the power amplifier 50a connected to the antenna 201V, the power amplifier 60a connected to the antenna 201H, the power amplifier 50b connected to the antenna 202V, the power amplifier 60b connected to the antenna 202H, the switched-capacitor circuit 20 configured to generate the plurality of discrete voltages based on the input voltage, the supply modulator 31 configured to selectively output at least one of the plurality of discrete voltages to the power amplifier 50a, the supply modulator 32 configured to selectively output at least one of the plurality of discrete voltages to the power amplifier 60a, the supply modulator 33 configured to selectively output at least one of the plurality of discrete voltages to the power amplifier 50b, and the supply modulator 34 configured to selectively output at least one of the plurality of discrete voltages to the power amplifier 60b. The power amplifiers 50a and 60a are configured to amplify the radio frequency signals in the first radio frequency band. The power amplifiers 50b and 60b are configured to amplify the radio frequency signals in the second radio frequency band on the higher frequency side relative to the first radio frequency band.

In the above, the plurality of discrete voltages to be supplied to the power amplifiers 50a, 50b, 60a, and 60b is generated by the same switched-capacitor circuit 20. Thus, the tracker circuit 4 can be downsized, thereby providing a small-size radio frequency circuit 6 including the power amplification system in the ET mode.

For example, in the radio frequency circuit 6, the supply modulator 31 is configured to select at least one of the plurality of discrete voltages in accordance with the first parallel data signal. The supply modulator 32 is configured to select at least one of the plurality of discrete voltages in accordance with the second parallel data signal different from the first parallel data signal. The supply modulator 33 is configured to select at least one of the plurality of discrete voltages in accordance with the third parallel data signal different from the first parallel data signal and the second parallel data signal. The supply modulator 34 is configured to select at least one of the plurality of discrete voltages in accordance with the fourth parallel data signal different from the first parallel data signal, the second parallel data signal, and the third parallel data signal.

In the above, the power supply voltages to be supplied to the power amplifiers 50a, 50b, 60a, and 60b can be optimized. Therefore, the distortion characteristics of the power amplifiers 50a, 50b, 60a, and 60b can be optimized. In an exemplary aspect, when the power amplifiers 50a, 50b, 60a, and 60b are operated by MIMO, the parameters of DPD circuits disposed upstream of the power amplifiers 50a, 50b, 60a, and 60b can be set individually. Therefore, the communication throughput can be improved.

For example, in the radio frequency circuit 6, the supply modulator 31 is configured to select at least one of the plurality of discrete voltages in accordance with the first parallel data signal. The supply modulator 32 is configured to select at least one of the plurality of discrete voltages in accordance with the first parallel data signal. The supply modulator 33 is configured to select at least one of the plurality of discrete voltages in accordance with the third parallel data signal different from the first parallel data signal. The supply modulator 34 is configured to select at least one of the plurality of discrete voltages in accordance with the third parallel data signal.

In the above, the same reference signal is transmitted from the antennas 201V and 201H, and the same reference signal is transmitted from the antennas 202V and 202H. Therefore, the optimum communication state can be obtained. Thus, the communication coverage can be improved.

For example, the radio frequency circuit 7A according to Modification 2 of the second embodiment further includes the power amplifier 70 connected to the antenna 203, and the supply modulator 35 configured to selectively output at least one of the plurality of discrete voltages to the power amplifier 70. The power amplifier 70 is configured to amplify the radio frequency signal in the Sub-6 band. The first radio frequency band and the second radio frequency band are each the millimeter wave band or the sub-terahertz band.

In the above, the plurality of discrete voltages to be supplied to the power amplifiers 50a, 50b, 60a, 60b, and 70 is generated by the same switched-capacitor circuit 20. Thus, the tracker circuit 4A can be downsized, thereby providing a small-size radio frequency circuit 7A including the power amplification system in the ET mode.

The radio frequency module 1C according to Example 3 (and the radio frequency module 1D according to Example 4) includes the module laminate 90, the integrated circuit 80C disposed on the module laminate 90, and the RFIC 5. The RFIC 5 includes the power amplifier 50a connected to the antenna 201V, the power amplifier 60a connected to the antenna 201H, the power amplifier 50b connected to the antenna 202V, and the power amplifier 60b connected to the antenna 202H. The integrated circuit 80C includes at least one switch included in the switched-capacitor circuit 20, and at least one switch included in each of the supply modulators 31 to 34. The switched-capacitor circuit 20 is configured to generate the plurality of discrete voltages based on the input voltage and output the plurality of generated discrete voltages to the supply modulators 31 to 34. The output terminal 251 of the supply modulator 31 included in the integrated circuit 80C is connected to the power amplifier 50a. The output terminal 252 of the supply modulator 32 included in the integrated circuit 80C is connected to the power amplifier 60a. The output terminal 253 of the supply modulator 33 included in the integrated circuit 80C is connected to the power amplifier 50b. The output terminal 254 of the supply modulator 34 included in the integrated circuit 80C is connected to the power amplifier 60b. The power amplifiers 50a and 60a are configured to amplify the radio frequency signals in the first radio frequency band. The power amplifiers 50b and 60b are configured to amplify the radio frequency signals in the second radio frequency band on the higher frequency side relative to the first radio frequency band.

In the above, the plurality of discrete voltages to be supplied to the power amplifiers 50a, 50b, 60a, and 60b is generated by the same switched-capacitor circuit 20. The switches of the tracker circuit 4 are integrated into the integrated circuit 80C. Thus, the radio frequency module 1C including the tracker circuit 4 can be downsized.

For example, in the radio frequency module 1C, the integrated circuit 80C and the RFIC 5 are disposed on the principal surface 90a, and the integrated circuit 80C is disposed to adjoin the RFIC 5.

In the above, the integrated circuit 80C is disposed to adjoin the RFIC 5. Therefore, the radio frequency module 1C can be downsized. The wire 404 connecting the output terminal 251 of the integrated circuit 80C and the input terminal 511 of the RFIC 5 can be shortened. The wire 403 connecting the output terminal 253 of the integrated circuit 80C and the input terminal 513 of the RFIC 5 can be shortened. The wire connecting the output terminal 252 of the integrated circuit 80C and the input terminal 512 of the RFIC 5 can be shortened. The wire connecting the output terminal 254 of the integrated circuit 80C and the input terminal 514 of the RFIC 5 can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

For example, in the radio frequency module 1D, the module laminate 90 has the principal surfaces 90a and 90b that face each other. The RFIC 5 is disposed on the principal surface 90a. The integrated circuit 80C is disposed on the principal surface 90b. In plan view of the principal surfaces 90a and 90b, the amplification transistor of the power amplifier 50a overlaps the integrated circuit 80C at least in part, the amplification transistor of the power amplifier 60a overlaps the integrated circuit 80C at least in part, the amplification transistor of the power amplifier 50b overlaps the integrated circuit 80C at least in part, and the amplification transistor of the power amplifier 60b overlaps the integrated circuit 80C at least in part.

In the above, the integrated circuit 80C and the RFIC 5 are disposed separately on both the principal surfaces of the module laminate 90. Therefore, the radio frequency module 1D can be downsized. The wire 405 connecting the output terminal 251 of the integrated circuit 80C and the input terminal 511 of the RFIC 5 can be shortened. The wire 406 connecting the output terminal 253 of the integrated circuit 80C and the input terminal 513 of the RFIC 5 can be shortened. The wire connecting the output terminal 252 of the integrated circuit 80C and the input terminal 512 of the RFIC 5 can be shortened. The wire connecting the output terminal 254 of the integrated circuit 80C and the input terminal 514 of the RFIC 5 can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

The radio frequency module 1E according to Example 5 (and the radio frequency module IF according to Example 6) further includes the RFICs 5A and 5B disposed on the module laminate 90. The RFIC 5A includes the power amplifiers 50a and 60a. The RFIC 5B includes the power amplifier 50b connected to the antenna 202V, and the power amplifier 60b connected to the antenna 202H. The integrated circuit 80E further includes at least one switch included in the supply modulator 33, and at least one switch included in the supply modulator 34. The switched-capacitor circuit 20 is configured to output the plurality of discrete voltages to the supply modulators 31 to 34. The output terminal 253 of the supply modulator 33 included in the integrated circuit 80E is connected to the power amplifier 50b. The output terminal 254 of the supply modulator 34 included in the integrated circuit 80E is connected to the power amplifier 60b. The power amplifiers 50a and 60a are configured to amplify the radio frequency signals in the first radio frequency band. The power amplifiers 50b and 60b are configured to amplify the radio frequency signals in the second radio frequency band on the higher frequency side relative to the first radio frequency band.

In the above, the integrated circuit 80E and the RFICs 5A and 5B are disposed on the single module laminate 90. Therefore, the radio frequency module 1E (and 1F) including the power amplifiers 50a, 50b, 60a, and 60b can be downsized.

For example, in the radio frequency module 1E, the integrated circuit 80E and the RFICs 5A and 5B are disposed on the principal surface 90a of the module laminate 90. In plan view of the principal surface 90a, the integrated circuit 80E is disposed between the RFIC 5A and the RFIC 5B, and the integrated circuit 80E is disposed to adjoin the RFIC 5A and is disposed to adjoin the RFIC 5B.

In the above, the integrated circuit 80E is disposed to adjoin the RFIC 5A, and the integrated circuit 80E is disposed to adjoin the RFIC 5B. Therefore, the radio frequency module 1E can be downsized. The wire 407 connecting the output terminal 251 of the integrated circuit 80E and the input terminal 511 of the RFIC 5A can be shortened. The wire 408 connecting the output terminal 253 of the integrated circuit 80E and the input terminal 513 of the RFIC 5B can be shortened. The wire connecting the output terminal 252 of the integrated circuit 80E and the input terminal 512 of the RFIC 5A can be shortened. The wire connecting the output terminal 254 of the integrated circuit 80E and the input terminal 514 of the RFIC 5B can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

For example, in the radio frequency module 1F, the module laminate 90 has the principal surfaces 90a and 90b that face each other. The RFICs 5A and 5B are disposed on the principal surface 90a. The integrated circuit 80F is disposed on the principal surface 90b. In plan view of the principal surfaces 90a and 90b, the amplification transistor of the power amplifier 50a overlaps the integrated circuit 80F at least in part, the amplification transistor of the power amplifier 60a overlaps the integrated circuit 80F at least in part, the amplification transistor of the power amplifier 50b overlaps the integrated circuit 80F at least in part, and the amplification transistor of the power amplifier 60b overlaps the integrated circuit 80F at least in part.

In the above, the integrated circuit 80F and the RFICs 5A and 5B are disposed separately on both the principal surfaces of the module laminate 90. Therefore, the radio frequency module 1F can be downsized. The wire 409 connecting the output terminal 251 of the integrated circuit 80F and the input terminal 511 of the RFIC 5A can be shortened. The wire 410 connecting the output terminal 253 of the integrated circuit 80F and the input terminal 513 of the RFIC 5B can be shortened. The wire connecting the output terminal 252 of the integrated circuit 80F and the input terminal 512 of the RFIC 5A can be shortened. The wire connecting the output terminal 254 of the integrated circuit 80F and the input terminal 514 of the RFIC 5B can be shortened. Thus, ringing of the power supply voltages to be supplied from the tracker circuit 4 to the power amplifiers 50a, 50b, 60a, and 60b, etc. can be suppressed to achieve stability. Therefore, the efficiency of the tracker circuit 4 can be improved.

For example, in the radio frequency modules 1C to 1F, the first radio frequency band and the second radio frequency band are each the millimeter wave band or the sub-terahertz band.

In the above, small-size radio frequency modules 1C to 1F can be provided that re configured to amplify the radio frequency signals in the millimeter wave band or the sub-terahertz band in the ET mode.

### Additional Exemplary Embodiments

Although the radio frequency circuit, the radio frequency module, and the radio frequency signal transmission method according to the present disclosure have been described above based on the embodiments, the radio frequency circuit, the radio frequency module, and the radio frequency signal transmission method described herein are not limited to the above embodiments. The exemplary aspects of the present disclosure encompass other embodiments implemented by combining any components in the above embodiments, various modifications to the above embodiments that are conceivable by those skilled in the art without departing from the spirit of the present disclosure, and various devices including the radio frequency circuit and the radio frequency module.

For example, in the circuit structures of the radio frequency circuits and the radio frequency modules according to the above embodiments, any other circuit element or wire may be inserted between the circuit elements disclosed in the drawings or the paths connecting the signal paths.

The exemplary aspects of the present disclosure are widely applicable to a communication device of a mobile phone and the like as a radio frequency circuit or a radio frequency module disposed on a front end portion adapted to a millimeter wave band or a sub-terahertz band.

### REFERENCE SIGNS LIST

1, 6, 7, 7A radio frequency circuit
1A, 1B, 1C, 1D, 1E, IF radio frequency module
2, 4, 4A tracker circuit
3A, 3B, 5, 5A, 5B RFIC
8 PAIC
9 communication device
10 pre-regulator circuit
10S PR switch portion
20 switched-capacitor circuit
20S SC switch portion
30A, 30B, 31, 32, 33, 34, 35 supply modulator
30AS, 30BS, 31S, 32S, 33S, 34S SM switch portion
40 digital control circuit
40S digital control portion
41 first controller
42 second controller
50, 50a, 50b, 60, 60a, 60b, 70 power amplifier
51, 51a, 51b, 61, 61a, 61b, 71 low-noise amplifier
52, 52a, 52b, 53, 53a, 53b, 62, 62a, 62b, 63, 63a, 63b phase shift circuit
54, 54a, 54b, 64, 64a, 64b, 74 switch
80A, 80C, 80E, 80F integrated circuit
90 module laminate
90a, 90b principal surface
91, 92 resin member
110, 131A, 131B, 132A, 132B, 133A, 133B, 134A, 134B, 501, 502, 511, 512, 513, 514 input terminal
111, 130A, 130B, 241, 242, 251, 252, 253, 254 output terminal
150 external connection terminal
200H, 201H, 202H, 200V, 201V, 202V, 203 antenna
261, 262, 263, 264 control signal terminal
300 BBIC
401, 402, 403, 404, 405, 406, 407, 408, 409, 410 wire
410a, 410b, 420a, 420b mixer
510, 520 local oscillator

What is claimed:

1. A radio frequency circuit comprising:
a first power amplifier connected to a first vertical polarization antenna;
a second power amplifier connected to a first horizontal polarization antenna;
a switched-capacitor circuit configured to generate a plurality of discrete voltages based on an input voltage;
a first supply modulator configured to selectively output at least one voltage of the plurality of discrete voltages to the first power amplifier; and
a second supply modulator configured to selectively output at least one voltage of the plurality of discrete voltages to the second power amplifier.

2. The radio frequency circuit according to claim 1, wherein:
the first supply modulator is configured to select the at least one voltage for the first power amplifier in accordance with a first parallel data signal; and
the second supply modulator is configured to select the at least one voltage for the second power amplifier in accordance with a second parallel data signal that is different from the first parallel data signal.

3. The radio frequency circuit according to claim 1, wherein:
the first supply modulator is configured to select the at least one voltage for the first power amplifier in accordance with a first parallel data signal; and
the second supply modulator is configured to select the at least one voltage for the second power amplifier in accordance with the first parallel data signal.

4. The radio frequency circuit according to claim 1, further comprising:
a third power amplifier connected to a second vertical polarization antenna;
a fourth power amplifier connected to a second horizontal polarization antenna;
a third supply modulator configured to selectively output at least one voltage of the plurality of discrete voltages to the third power amplifier; and
a fourth supply modulator configured to selectively output at least one voltage of the plurality of discrete voltages to the fourth power amplifier,
wherein the first power amplifier and the second power amplifier are configured to amplify radio frequency signals in a first radio frequency band; and
wherein the third power amplifier and the fourth power amplifier are configured to amplify radio frequency signals in a second radio frequency band that is on a higher frequency side than the first radio frequency band.

5. The radio frequency circuit according to claim 4, wherein:
the first supply modulator is configured to select the at least one voltage for the first power amplifier in accordance with a first parallel data signal;
the second supply modulator is configured to select the at least one voltage for the second power amplifier in accordance with a second parallel data signal different from the first parallel data signal;
the third supply modulator is configured to select the at least one voltage for the third power amplifier in accordance with a third parallel data signal that is different from the first and second parallel data signals; and
the fourth supply modulator is configured to select the at least one voltage for the fourth power amplifier in accordance with a fourth parallel data signal that is different from the first, second and third parallel data signals.

6. The radio frequency circuit according to claim 4, wherein:
the first supply modulator is configured to select the at least one voltage for the first power amplifier in accordance with a first parallel data signal;
the second supply modulator is configured to select the at least one voltage for the second power amplifier in accordance with the first parallel data signal;
the third supply modulator is configured to select the at least one voltage for the third power amplifier in accordance with a third parallel data signal different from the first parallel data signal; and
the fourth supply modulator is configured to select the at least one voltage for the fourth power amplifier in accordance with the third parallel data signal.

7. The radio frequency circuit according to claim 4, further comprising:
a fifth power amplifier connected to a first antenna; and
a fifth supply modulator configured to selectively output at least one voltage of the plurality of discrete voltages to the fifth power amplifier,
wherein the fifth power amplifier is configured to amplify a radio frequency signal in a Sub-6 band; and
wherein the first radio frequency band and the second radio frequency band are each a millimeter wave band or a sub-terahertz band.

8. A radio frequency module comprising:
a module laminate; and
a first integrated circuit disposed on the module laminate and including at least one switch included in a switched-capacitor circuit, at least one switch included in a first supply modulator, and at least one switch included in a second supply modulator;
wherein the switched-capacitor circuit is configured to generate a plurality of discrete voltages based on an input voltage, and output the plurality of generated discrete voltages to the first supply modulator and the second supply modulator,
wherein a first output terminal of the first supply modulator included in the first integrated circuit is connected to a first power amplifier connected to a first vertical polarization antenna, and
wherein a second output terminal of the second supply modulator included in the first integrated circuit is connected to a second power amplifier connected to a first horizontal polarization antenna.

9. The radio frequency module according to claim 8, further comprising:
a second integrated circuit including:
the first power amplifier, and
a first phase shift circuit connected to an input end of the first power amplifier; and
a third integrated circuit including:
the second power amplifier, and
a second phase shift circuit connected to an input end of the second power amplifier.

10. The radio frequency module according to claim 9, wherein:
the first integrated circuit, the second integrated circuit, and the third integrated circuit are disposed on a first principal surface of the module laminate; and
the first integrated circuit adjoins the second integrated circuit that adjoins the third integrated circuit.

11. The radio frequency module according to claim 9, wherein:
the module laminate has a first principal surface and a second principal surface that are opposite each other,
the second integrated circuit and the third integrated circuit are disposed on the first principal surface,
the first integrated circuit is disposed on the second principal surface, and
in a plan view of the first principal surface and the second principal surface, an amplification transistor of the first power amplifier at least partially overlaps the first integrated circuit, and an amplification transistor of the second power amplifier at least partially overlaps the first integrated circuit.

12. The radio frequency module according to claim 8, further comprising:
a fourth integrated circuit including:
the first power amplifier,
the second power amplifier,
a third power amplifier connected to a second vertical polarization antenna, and
a fourth power amplifier connected to a second horizontal polarization antenna,
wherein the first integrated circuit further includes at least one switch included in a third supply modulator, and at least one switch included in a fourth supply modulator,
wherein the switched-capacitor circuit is configured to output the plurality of discrete voltages to the first supply modulator, the second supply modulator, the third supply modulator, and the fourth supply modulator,
a third output terminal of the third supply modulator included in the first integrated circuit is connected to the third power amplifier,
a fourth output terminal of the fourth supply modulator included in the first integrated circuit is connected to the fourth power amplifier,
the first power amplifier and the second power amplifier are configured to amplify radio frequency signals in a first radio frequency band, and
the third power amplifier and the fourth power amplifier are configured to amplify radio frequency signals in a second radio frequency band that is on a higher frequency side than the first radio frequency band.

13. The radio frequency module according to claim 12, wherein the first integrated circuit and the fourth integrated circuit are disposed on a first principal surface of the module laminate.

14. The radio frequency module according to claim 12, wherein:
the module laminate has a first principal surface and a second principal surface that are opposite each other,
the fourth integrated circuit is disposed on the first principal surface;
the first integrated circuit is disposed on the second principal surface, and
in a plan view of the first principal surface and the second principal surface, an amplification transistor of the first power amplifier at least partially overlaps the first integrated circuit, an amplification transistor of the second power amplifier at least partially overlaps the first integrated circuit, an amplification transistor of the third power amplifier at least partially overlaps the first integrated circuit, and an amplification transistor of the fourth power amplifier at least partially overlaps the first integrated circuit.

15. The radio frequency module according to claim 8, further comprising:
a fifth integrated circuit that includes the first power amplifier and the second power amplifier,
a sixth integrated circuit that includes:
a third power amplifier connected to a second vertical polarization antenna, and
a fourth power amplifier connected to a second horizontal polarization antenna,
wherein the first integrated circuit further includes at least one switch included in a third supply modulator, and at least one switch included in a fourth supply modulator,
wherein the switched-capacitor circuit is configured to output the plurality of discrete voltages to the first supply modulator, the second supply modulator, the third supply modulator, and the fourth supply modulator,
wherein a third output terminal of the third supply modulator included in the first integrated circuit is connected to the third power amplifier,
wherein a fourth output terminal of the fourth supply modulator included in the first integrated circuit is connected to the fourth power amplifier,
wherein the first power amplifier and the second power amplifier are configured to amplify radio frequency signals in a first radio frequency band, and
wherein the third power amplifier and the fourth power amplifier are configured to amplify radio frequency signals in a second radio frequency band that is on a higher frequency side than the first radio frequency band.

16. The radio frequency module according to claim 15, wherein:
the first integrated circuit, the fifth integrated circuit, and the sixth integrated circuit are disposed on a first principal surface of the module laminate, and
in a plan view of the first principal surface, the first integrated circuit is disposed between the fifth integrated circuit and the sixth integrated circuit.

17. The radio frequency module according to claim 15, wherein:
the module laminate has a first principal surface and a second principal surface that is opposite each other,
the fifth integrated circuit and the sixth integrated circuit are disposed on the first principal surface,
the first integrated circuit is disposed on the second principal surface, and
in a plan view of the first principal surface and the second principal surface, an amplification transistor of the first power amplifier at least partially overlaps the first integrated circuit, an amplification transistor of the second power amplifier at least partially overlaps the first integrated circuit, an amplification transistor of the third power amplifier at least partially overlaps the first integrated circuit, and an amplification transistor of the fourth power amplifier at least partially overlaps the first integrated circuit.

18. The radio frequency module according to claim 12, wherein the first radio frequency band and the second radio frequency band are each a millimeter wave band or a sub-terahertz band.

19. A radio frequency signal transmission method comprising:
generating a plurality of discrete voltages based on an input voltage;
selectively supplying at least one voltage of the plurality of discrete voltages to a first power amplifier based on an envelope signal of a first radio frequency signal;
selectively supplying at least one voltage of the plurality of discrete voltages to a second power amplifier based on an envelope signal of a second radio frequency signal;
amplifying the first radio frequency signal by the first power amplifier and radiating a vertically polarized signal; and
amplifying the second radio frequency signal by the second power amplifier and radiating a horizontally polarized signal.

20. The radio frequency signal transmission method according to claim 19, wherein a timing to selectively supply the at least one voltage to the first power amplifier based on the envelope signal of the first radio frequency signal is a same timing as a timing to selectively supply at least one voltage to the second power amplifier based on the envelope signal of the second radio frequency signal.
